(19) United States
(12) Patent Application Publication
(10) Pub. No.: US 2023/0383607 A1
(43) Pub. Date: Nov. 30, 2023

(54) MULTIPLE INTERMEDIATE STEP SIMULATION OF DRILL BIT ABRASIVE WEAR

(71) Applicant: Halliburton Energy Services, Inc., Houston, TX (US)

(72) Inventors: Shilin Chen, Montgomery, TX (US); Christopher Charles Propes, Montgomery, TX (US)

(21) Appl. No.: 17/826,509

(22) Filed: May 27, 2022

(51) Int. Cl. E21B 12/02; E21B 45/00; E21B 44/00

(52) U.S. Cl. CPC E21B 12/02; E21B 45/00; E21B 44/00; E21B 2200/20; E21B 2200/22

(57) ABSTRACT

A method comprises determining an initial bit profile of a drill bit prior to the drill bit being used for drilling a wellbore. The method comprises determining a wear depth for at least one element of the drill bit after the drill bit has drilled at least a portion of the wellbore and determining a final bit profile of the drill bit based on the wear depth for the at least one element of the drill bit. The method comprises performing the following for each of one or more intermediate steps between the initial bit profile and the final bit profile, determining an intermediate bit profile of the drill bit and determining at least one wear parameter for the at least one element based on the intermediate bit profile of the drill bit.

### BACKGROUND

The disclosure generally relates to drilling of wellbores and more particularly, to abrasive wear and damage simulation and evaluation of drill bits used for such drilling.

Various types of drilling bits have been used to form wellbores in different types of subsurface formations. Examples of such drill bits can include fixed cutter drill bits, drag bits, polycrystalline diamond compact (PDC) drill bits, and matrix drill bits associated with forming oil and gas wells extending through one or more subsurface formations. Fixed cutter drill bits such as a PDC bit may include multiple blades that each include multiple cutting elements.

As a drill bit is used in a typical drilling application, the cutting elements can experience abrasive wear and/or damage. As a cutting element wears and/or is damaged, it becomes less effective and has a higher likelihood of failure. Cutting element wear and damage may have a significant effect on the rate of penetration (ROP). The ROP is important for reducing costs during drilling operations as an increase in the ROP can reduce operating time. ROP can be impacted by several variables including the drill bit type, geological formation characteristics, drilling fluid properties, operating conditions, drill bit hydraulics, and cutting element wear and damage.

### BRIEF DESCRIPTION OF THE DRAWINGS

Embodiments of the disclosure may be better understood by referencing the accompanying drawings.

FIG. 1 depicts an example well system, according to some embodiments.

FIGS. 2A-2B are an overhead view and an isometric view, respectively, of an example drill bit, according to some embodiments.

FIG. 3 depicts a flowchart of example operations to simulate abrasive wear or damage of a drill bit depending on the primary cause of the dulling of the drill bit, according to some embodiments.

FIG. 4 depicts a flowchart of example operations to simulate of abrasive wear of a drill bit during drilling a wellbore with the drill bit, according to some embodiments.

FIG. 5A-5B depict an example three-dimensional (3D) distribution of elements and an associated initial element wear profile, respectively, according to some embodiments.

FIG. 6A-6B depicts graphs of an example initial bit profile, multiple intermediate bit profiles, and final bit profile of a drill bit, according to some embodiments.

FIG. 7 depicts an example graph of wear depth over multiple intermediate steps, according to some embodiments.

FIG. 8A-8B depict an example three-dimensional (3D) distribution of elements and an associated intermediate element wear profile, respectively, according to some embodiments.

FIG. 9A-9B depict a radial path of a pair of track-set cutters and the combined element wear profile of the track-set cutters, respectively, according to some embodiments.

FIG. 10 depicts an example graph of an ROP over a number of intermediate steps of the simulation, according to some embodiments.

FIG. 11 depicts a flowchart of example operations to simulate damaged cutters of a drill but during drilling a wellbore with the drill bit, according to some embodiments.

FIG. 12A-12B depict an example three-dimensional (3D) distribution of primary cutters and associated primary cutter profiles, respectively, according to some embodiments.

FIG. 13A-13B depict an example three-dimensional (3D) distribution of both primary cutters and backup cutters and associated primary cutter profiles and backup cutter profiles, respectively, according to some embodiments.

FIG. 14 depicts an example graph of a horizontal radius versus a vertical radius versus of a cutter face having nonlinear wear depths, according to some embodiments.

FIGS. 15A-15C depict example graphs of changes in different drill bit characteristics across intermediate steps of the simulation, according to some embodiments.

FIG. 16 depicts an example multi-well system, according to some embodiments.

FIG. 17 depicts a flowchart of example operations for application of abrasive wear and/or damaged drill bit simulation in a multi-well system, according to some embodiments.

FIG. 18 depicts an example computer, according to some embodiments.

### DESCRIPTION

The description that follows includes example systems, methods, techniques, and program flows that embody aspects of the disclosure. However, it is understood that this disclosure may be practiced without these specific details. For instance, this disclosure refers to PDC drill bits in illustrative examples. Aspects of this disclosure can also be applied to any other types of drill bits or drilling tools. In other instances, well-known instruction instances, protocols, structures, and techniques have not been shown in detail in order not to obfuscate the description.

Example embodiments can include simulation of abrasive wear and/or damage of a drill bit. Such simulation can be used to determine how and what causes abrasive wear and/or damage of a drill bit. Example embodiments can perform such simulation based on an initial profile of a drill bit prior to drilling and a final profile of the drill bit after drilling. Some embodiments can be performed without using a cutter wear or damage model.

For example, for abrasive wear simulation, the initial bit wear can be zero and represented by a new bit profile. The final condition of the drill bit can be represented by a digital dull after drilling at least a portion of a wellbore. In some implementations, for each cutter of the drill bit, the wear depth can be nonlinearly divided into N steps. At each step, a bit wear profile and profiles for different elements of the drill bit can be determined. For example, the elements can include primary cutters, backup cutters, and depth of cut controllers (DOCC). Additionally, a bit-rock interaction model can be executed to obtain bit design characteristics for the drill bit.

Conventional bit wear simulation is usually based on a cutter wear model. For such a simulation, the wear depth is assumed to be proportional to cutter forces, cutting velocity, temperature, and rock properties. However, the problem with this conventional approach is that during drilling, the cutter forces and rock properties are typically unknown. Accordingly, the cutter wear model may not be able to represent the actual cutter wear. Therefore, example embodiments perform drill bit wear simulation without using a cutter wear model. Additionally, example embodiments can nonlinearly divide the cutter wear into multiple steps, wherein bit-rock interaction simulation can be performed at each step. In some embodiments, a force model of a worn cutter can be validated by field measurements. Also, understanding of how abrasive wear of the drill bit can affect performance of the drill bit can be applied to drilling optimization and to save cost of drilling operations.

Similar to abrasive wear of drill bits, drill bits (including cutters thereon) can be damaged during drilling. How such damage affect performance of the drill bit may be unknown. Also similar to abrasive wear, damage to the drill bit can be based on an initial bit profile prior to drilling and a final condition that includes damage conditions of the drill bit after drilling. Drill bit damage simulation can include a bit-rock interaction. In some implementations, the damage simulation can be nonlinearly divided into N steps, wherein each step can represent drill bit damage status. In some embodiments, simulation can include different types of drill bit motion (such as axial bit motion, lateral bit motion, etc.).

A cutter of the drill bit can be damaged by cutting into or impact with a hard rock being drilled. Conventional approaches perform damage evaluation of a drill bit after drilling. In contrast, example embodiments can include a non-linear step by step damage determination from the initial bit profile to the final condition after drilling. Each such step can be associated with a dull status of the drill bit. Also, each step can include an evaluation of various characteristics of the drill bit. Similar to abrasive wear, understanding of how damage of the drill bit can affect performance of the drill bit can be applied to drilling optimization and to save cost of drilling operations. Additionally, prediction of rate of penetration during actual drilling can be made once simulation results are calibrated.

### Example Well System

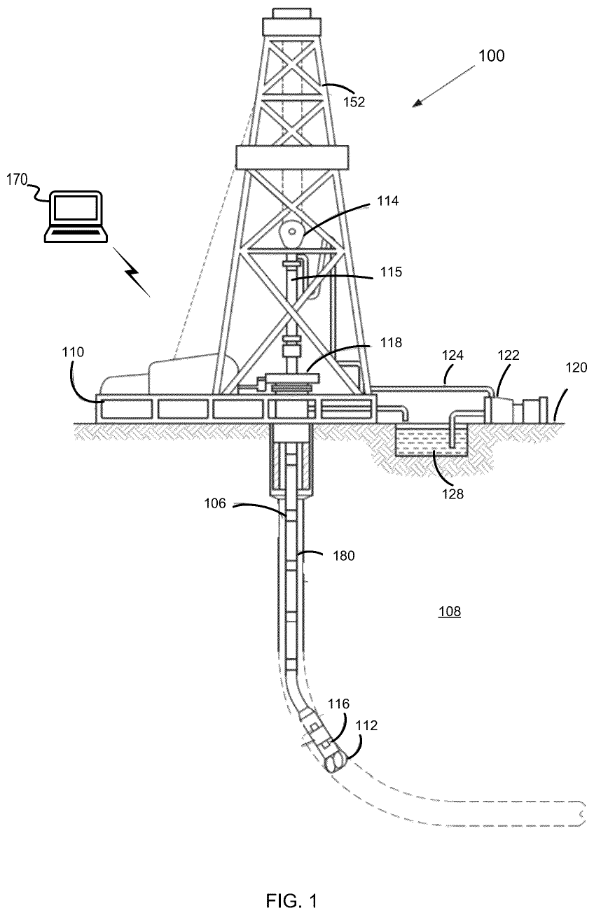

FIG. 1 depicts an example well system, according to some embodiments. In particular, FIG. 1 is a schematic diagram of a well system 100 that includes a drill string 180 having a drill bit 112 disposed in a wellbore 106 for drilling the wellbore 106 in the subsurface formation 108. While depicted for a land-based well system, example embodiments can be used in subsea operations that employ floating or sea-based platforms and rigs. The drill bit 112 is an example drill bit for which simulation of abrasive wear and damage as described herein can be performed.

The well system 100 may further include a drilling platform 110 that supports a derrick 152 having a traveling block 114 for raising and lowering the drill string 180. The drill string 180 may include, but is not limited to, drill pipe, drill collars, and down hole tools 116. The down hole tools 116 may comprise any of a number of different types of tools including measurement while drilling (MWD) tools, logging while drilling (LWD) tools, mud motors, and others. A kelly 115 may support the drill string 180 as it may be lowered through a rotary table 118. The drill bit 112 may include roller cone bits, polycrystalline diamond compact (PDC) bits, natural diamond bits, any hole openers, reamers, coring bits, and the like. As the drill bit 112 rotates, it may crush or cut rock to create and extend a wellbore 106 that penetrates various subterranean formations. The drill bit 112 may be rotated by various methods including rotation by a downhole mud motor and/or via rotation of the drill string 180 from the surface 120 by the rotary table 118. Attributes of drilling the wellbore may be adjusted to increase, decrease, and/or maintain the rate of penetration (ROP) of the drill bit 112 through the subsurface formation 108. Attributes may include weight-on-bit (WOB) and rotations-per-minute (RPM) of the drill string 180. In some embodiments, the drill bit 112 may become dull and lose efficiency, thus requiring more WOB and/or RPM to maintain a target ROP. A pump 122 may circulate drilling fluid through a feed pipe 124 to the kelly 116, downhole through interior of the drill string 180, through orifices in the drill bit 112, back to the surface 120 via an annulus surrounding the drill string 180, and into a retention pit 128.

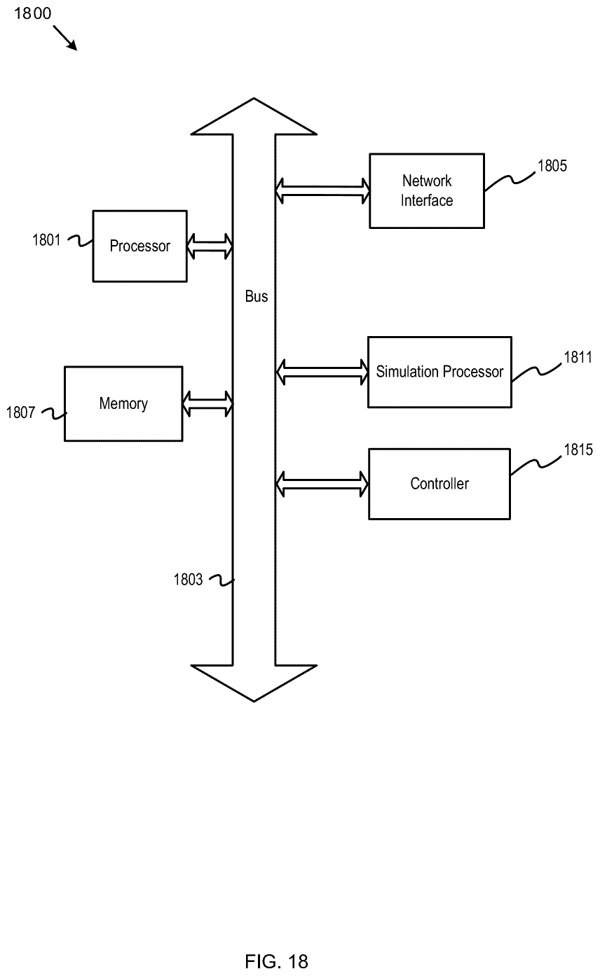

The well system 100 includes a computer 170 that may be communicatively coupled to other parts of the well system 100. The computer 170 can be local or remote to the drilling platform 110. A processor of the computer 170 may have perform simulations (as further described below). In some embodiments, the processor of the computer 170 may control drilling operations of the well system 100 or subsequent drilling operations of other wellbores. An example of the computer 170 is depicted in FIG. 18, which is further described below.

### Example Drill Bit

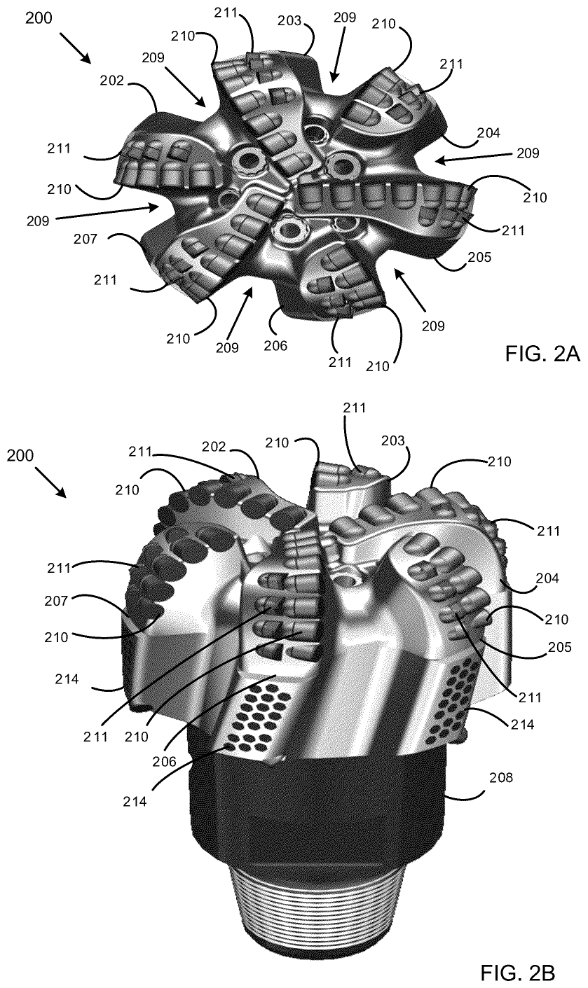

FIGS. 2A-2B are an overhead view and an isometric view, respectively, of an example drill bit, according to some embodiments. In particular, FIGS. 2A-2B depict an example drill bit 200. The drill bit 200 can be an example of the drill bit 112 of FIG. 1. As shown in this example, the drill bit 200 includes six blades 202-207, which can be integrally formed and extend from a bit body 208. The blades 202-207 are separated by flow channels 209 that may include nozzles (i.e., orifices) where drilling mud can be ejected through the drill bit 200 and into the wellbore. Primary cutters 210, backup cutters 211, and depth of cut controllers (DOCCs) 230 may be mounted on the blades 202-207. During drilling, the face of the primary cutters 210 and backup cutters 211 can be in contact with and cut and/or shear the rock of the subsurface formation to create and extend a wellbore. In some instances, the face of the primary cutters 210 may be extended a greater distance from the blades 202-207 than the backup cutters 211 such that only the primary cutters 210 can be in contact with the rock of the subsurface formation. During drilling, the primary cutters 210 may become worn or broken such that one or more of the backup cutters 211 can then be in contact with the rock of the subsurface formation. Many factors including orientation, shape, type, and density of the cutters may vary depending on the design of the drill bit 200. Pads 214 may extend from the side of the blades 202-207. The pads 214 may help maintain the size of the wellbore to a full gauge diameter, particularly when cutters become dull and become under gauge.

### Example Operations of Drill Bit Abrasive Wear and Damage Simulation

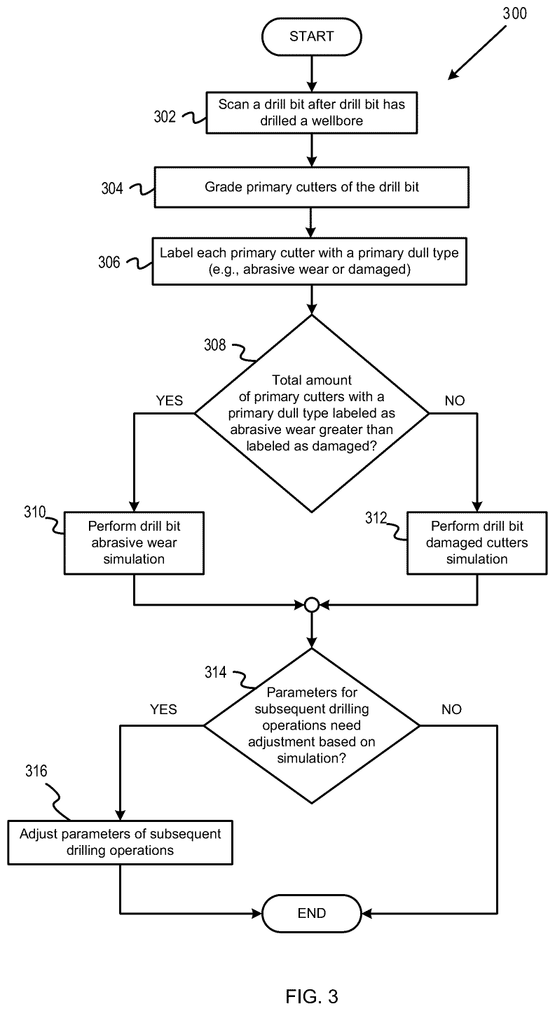

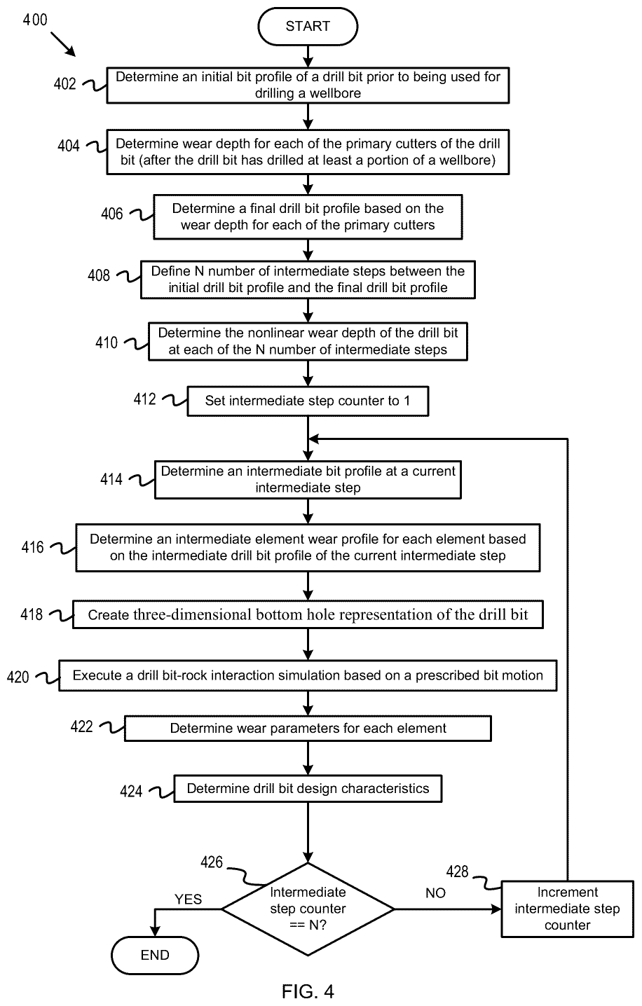

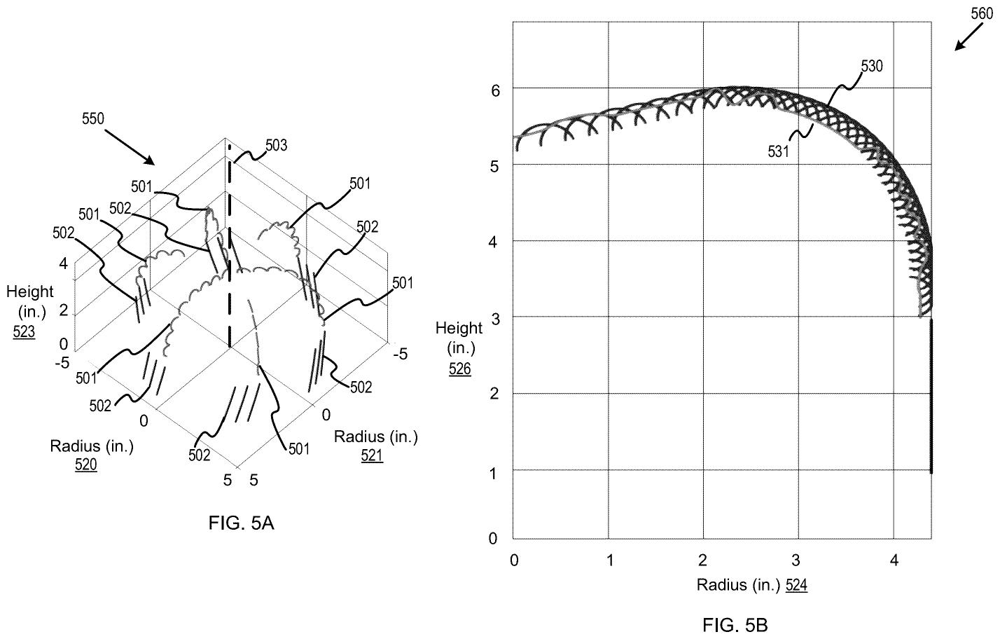

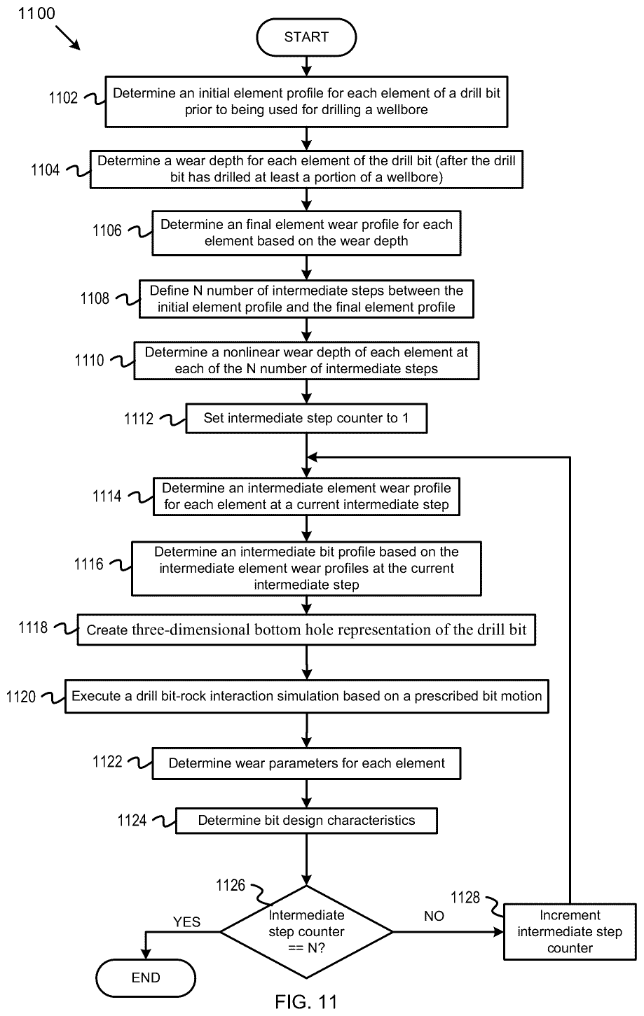

Example operations for simulating abrasive wear and damage of a drill bit are now described in reference to FIGS. 3-15. FIG. 3 depicts a flowchart of example operations to simulate abrasive wear or damage of a drill bit depending on the primary cause of the dulling of the drill bit. FIG. 4 depicts a flowchart of example operations for simulation of abrasive wear of a drill bit (more detailed example operations at block 308 of FIG. 3). FIG. 11 depicts a flowchart of example operations for simulation of damage of a drill bit (more detailed example operations at block 310 of FIG. 3). FIGS. 5-10 and 12-15 depict example graphs to help illustrate the example operations in the flowcharts of FIGS. 3 and 11, respectively.

FIG. 3 depicts a flowchart of example operations to simulate abrasive wear or damage of a drill bit depending on the primary cause of the dulling of the drill bit, according to some embodiments. The primary dull of the drill bit can determine the type of simulation that is to be performed on the drill bit and results of the simulation can be used to modify or update subsequent drilling operations. FIG. 3 depicts a flowchart 300 of operations that can determine the primary dull of the drill bit using a digital grading system. Operations of the flowchart 300 are described in reference to the well system 100 of FIG. 1. Operations of the flowchart 300 start at block 302.

At block 302, the drill bit is scanned after the drill bit has drilled at least a portion of a wellbore. For example, with reference to FIG. 1, a processor of the computer 170 can perform such scanning. Prior to drilling the wellbore, the bit may be new, and the cutters of the drill bit may have zero wear. After drilling the wellbore, the bit may be scanned to determine dull measurements of each primary cutter. In some embodiments, the drill bit may be scanned with an automated digital grading system to determine dull measurements of each primary cutter. The drill bit may also be scanned manually or by other digital systems that may require manual intervention. Each element of the drill bit (including primary cutters, backup cutters, DOCCs, and pads) may be scanned to determine the respective dull measurement. Dull measurements comprise comparing the cutter characteristics after the drill bit is used to drill the wellbore to the cutter characteristics before being used. A dull measurement can include the amount of cutter material remaining, the shape of the remaining cutter, etc. The shape may signify if the cutter was worn, broken, or chipped. The integrity of the cutter can be measured such as if the cutter body is cracked or delaminated. The dull measurement may also determine if the cutter is still in place on the blade of the drill bit.

At block 304, the primary cutters of the drill bit are graded based on the dull measurements. For example, with reference to FIG. 1, a processor of the computer 170 can perform this grading. In some embodiments, the computer 170 can perform this grading using an automated digital grading system.

At block 306, each primary cutter is labeled with a primary dull type (e.g., abrasive wear or damaged) based on the grading. For example, with reference to FIG. 1, a processor of the computer 170 can perform this operation. The primary cutters may be assigned an identifier. For example, if there are 40 primary cutters on the drill bit, then each primary cutter can be assigned a number 1-40. The primary cutters may also be grouped by the location of the primary cutter on the drill bit. For example, the groups may comprise cone, nose, shoulder, and gauge of the drill bit. Each primary cutter can be labeled with a primary dull type and the severity of the dull based on the dull measurements of the respective primary cutter. Primary dull types may include green dull, worn cutters, broken cutters, chipped cutters, delaminated cutters, and lost cutters. The primary dull types can further be grouped into three categories: zero wear, abrasive wear, and damaged cutter. If a primary cutter is graded with green dull, the primary cutter can be considered a primary cutter with zero wear. Primary cutters with primary dull types such as worn cutter can be considered primary cutters with abrasive wear. Primary cutters with primary dull types such as broken cutters, chipped cutters, delaminated cutters, and lost cutters can be considered primary cutters with damaged cutters. The severity of the primary dull type can also be determined by the automated digital grading system. For example, the severity of the primary dull type for each primary cutters may be graded on a scale of 0-8, where 0 is the least severe and 8 is the greatest severity.

At block 308, a determination is made of whether the total amount of primary cutters with abrasive wear is greater than the total amount of primary cutters with damaged cutters. For example, with reference to FIG. 1, a processor of the computer 170 can make this determination. For instance, if there are more primary cutters with abrasive wear than primary cutters with damaged cutters, then the primary dull of the drill bit can be considered to be abrasive wear. In contrast, if there are more primary cutters with damaged cutters than primary cutters with abrasive wear, then the primary dull of the drill bit can be considered to be damaged cutters. If the number of primary cutters with abrasive wear is equal to the number of primary cutters that are damaged, then different criteria can be used to determine whether to perform abrasive wear simulation (see block 310) or damaged cutter simulation (see block 312). Examples of such criteria can be an operator setting when these ties occur, whether there were more primary cutters with abrasive wear or damage in previous operations of the flowchart 300 with the same attributes as the current operations, etc. Examples of such attributes can be the type of drill bit, the type of primary cutters, the type of subsurface formation being drilled, if the same or different wellbore, etc. For instance, if the number of primary cutters with abrasive wear is equal to the number of primary cutters that are damaged, and if previous operations on the same wellbore resulted in the number of primary cutters having abrasive wear being greater than the number of primary cutters having damage, then a drill bit abrasive wear simulation is performed. In some embodiments, the total amount of primary cutters with zero wear is not considered when determining the primary dull of the drill bit if there is at least one primary cutter with abrasive wear and/or damaged cutters. For example, the processor of the computer 170 may determine that a drill bit with 40 primary cutters has 4 primary cutters with green wear, 1 primary cutter is broken, 1 primary cutter is delaminated, and 34 cutters have abrasive wear. Accordingly, there are 3 primary cutters with zero wear, 2 primary cutters with damaged cutters, and 34 primary cutters with abrasive wear. Therefore, the primary dull for the drill bit is abrasive wear. In another example, the processor of the computer 170 may determine that a drill bit with 40 primary cutters has 24 primary cutters with green dull, 4 primary cutters with abrasive wear, 8 primary cutters are broken, and 4 primary cutters are delaminated. Accordingly, there are 24 primary cutters with zero wear, 4 primary cutters with abrasive wear, and 12 primary cutters with damaged cutters. Therefore, the primary dull for the drill bit is damaged cutters. In some embodiments, the primary dull for the drill bit can be manually determined. For example, a drill bit design engineer can determine if the primary dull of the drill bit is abrasive wear or damaged cutter based on the number of cutters with zero wear, abrasive wear, and/or damaged cutters. If the total amount of primary cutters with abrasive wear is greater than the total amount of primary cutters with damaged cutters, then operations of the flowchart 300 continue to block 308. Otherwise, operations continue to block 310.

At block 310, simulation of abrasive wear of a drill bit is performed. For example, with reference to FIG. 1, a processor of the computer 170 can perform this simulation. Example operations of this simulation of abrasive wear of a drill bit is further described below in reference to FIG. 4.

At block 312, simulation of damaged cutters of a drill bit is performed. For example, with reference to FIG. 1, a processor of the computer 170 can perform this simulation. Example operations of this simulation of damaged cutters of a drill bit is further described below in reference to FIG. 11.

In some implementations, operations for using the output of the simulation can be performed (as described in reference to blocks 314-316 (now described).

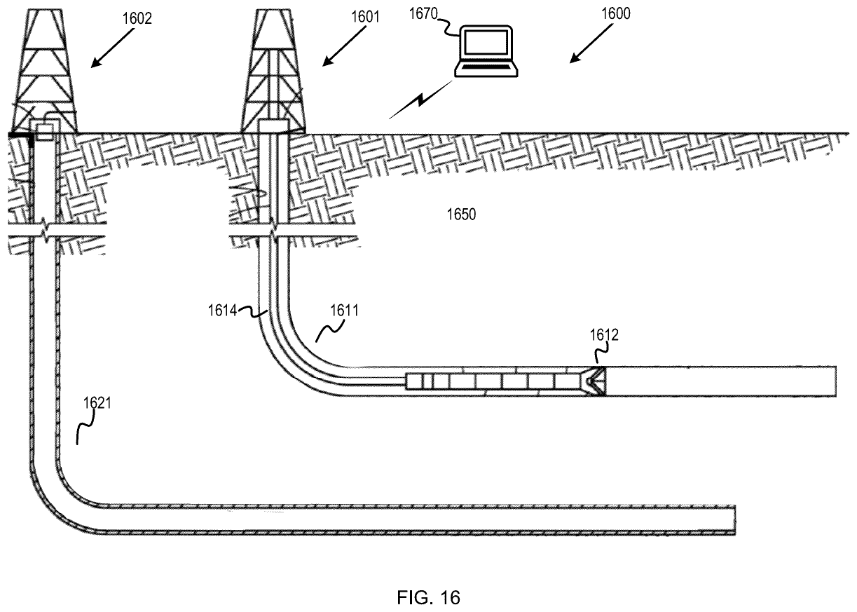

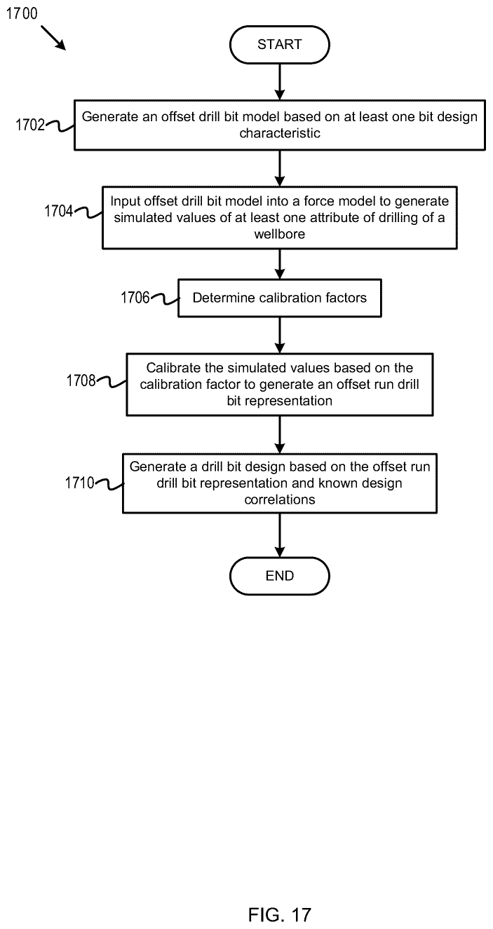

At block 314, a determination is made of whether parameters for subsequent drilling operations need adjustment based on the simulation. For example, with reference to FIG. 1, a processor of the computer 170 can make this determination. For instance, the parameters (such as WOB, TOB, etc.) for a subsequent drilling operation of the current wellbore or a different wellbore can be adjusted based on the simulation. As an example, the WOB can be adjusted if it is determined that too many primary cutters of the drill bit were damaged prematurely. For example, if more than two primary cutters were damaged before drilling 50 feet of the wellbore, parameters can be made for subsequent drilling operations to lower the WOB. An example application across multiple wellbores is further described below in reference to FIGS. 16-17. If it is determined that adjustment of parameters for subsequent drilling operations is needed, operations of the flowchart 300 continue at block 316. Otherwise, operations of the flowchart 300 are complete.

At block 316, parameters for subsequent drilling operations are adjusted based on the simulation. For example, with reference to FIG. 1, a processor of the computer 170 can perform this adjustment (as described above). Operations of the flowchart 300 are complete.

FIG. 4 depicts a flowchart of example operations to simulate abrasive wear of a drill bit during drilling a wellbore with the drill bit, according to some embodiments. In reference to FIG. 3, FIG. 4 depicts a flowchart 400 of example operations at block 310 of the flowchart 300. Abrasive wear on the drill bit can be steady state wear in which the cutters are worn over time as the drill bit drills the subsurface formation. The simulation may help determine drill bit design characteristics at intermediate steps of the drilling process that may be otherwise unknown due to unknown forces on the cutters of the drill bit while drilling and unknown rock properties of the subsurface formation. Example operations are described with reference to a drill bit abrasive wear simulator. The name chosen for the program code is not to be limiting on the claims. Structure and organization of a program can vary due to platform, programmer/architect preferences, programming language, etc. In addition, names of code units (programs, modules, methods, functions, etc.) can vary for the same reasons and can be arbitrary. The operations of flowchart 400 divide the simulation into steps such that bit design characteristics can be determined at intermediate steps between when the drill bit is new and when the drill bit is pulled from the wellbore after it has drilled said wellbore. For the example operations in flowchart 400, the subject drill bit has a primary dull of abrasive wear, which may be determined by the operations described in FIG. 3. Operations of the flowchart 400 start at block 402.

At block 402, an initial bit profile of a drill bit is determined. For example, with reference to FIG. 1, a processor of the computer 170 can make this determination. In some embodiments, the initial bit profile can be generated based on the distribution of the primary cutters of the drill bit. To help illustrate, FIG. 5A-5B depict an example three-dimensional (3D) distribution of elements and an associated initial element wear profile, respectively, according to some embodiments.

FIG. 5A depicts a spherical coordinate system 550 having an x-axis 520, a y-axis 521, and a z-axis 523. The x-axis 520 and the y-axis 521 are the radius of the drill bit in their respective directions and having units of inches (in.). The z-axis 523 is the height of the drill bit and also having units of inches (in.). A central axis 503 of the drill bit is parallel with z-axis 523 and perpendicular with the x-axis 520 and the y-axis 521. In this example, pads 502 are also displayed in the spherical coordinate system 550. While not shown, additional elements such as backup cutters and DOCCs can also be displayed in the spherical coordinate system 550.

The distribution of the primary cutters 501 and the pads 502 can correspond to the distribution of the blades of a drill bit. For example, the drill bit in FIG. 5A has six blades. A radial plane extending from central axis 503 corresponding to each blade can be used to project the corresponding primary cutters 501 and pads 502 into a cartesian coordinate system 560, as depicted in FIG. 5B. The cartesian coordinate system 560 includes an x-axis 524 that is the radius of the drill bit and a y-axis 526 that is the height of the drill bit. Both the x-axis 524 and the y-axis 526 have units of inches (in.).

The primary cutters 501 and the pads 502 from the spherical coordinate system 550 of FIG. 5A can be projected into the cartesian coordinate system 560 of FIG. 5B to generate initial element wear profiles 530 for each primary cutter and pad. The cartesian coordinate system 560 also includes final bit profile that is further described below.

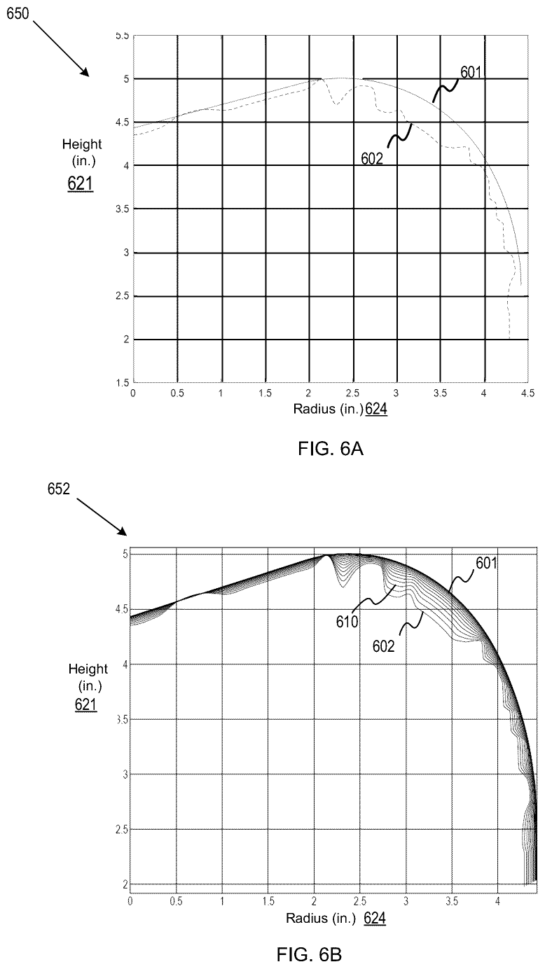

Returning to block 402 of flowchart 400, the initial bit profile can then be generated from the initial element wear profiles 530. For example, with reference to FIG. 1, a processor of the computer 170 can generate the initial bit profile from the initial element wear profile with different types of interpolation (such as one-dimensional interpolation). To help illustrate, FIG. 6A-6B depicts graphs of an example initial bit profile, multiple intermediate bit profiles, and final bit profile of a drill bit, according to some embodiments. FIGS. 6A-6B depict a graph 650 and a graph 652, respectively, that includes a y-axis 621 that is the height of drill bit and an x-axis 624 that is the radius of drill bit (both defined in units of inches (in.)). The graphs 650-652 include an initial bit profile 601 in a cartesian coordinate system that has been generated from initial element wear profiles 530.

At block 404, the wear depth of each of the primary cutters is determined after the drill bit has drilled at least a portion of a wellbore. For example, with reference to FIG. 1, a processor of the computer 170 can make this determination. In some embodiments, the wear depth can be determined by the dull measurements of the drill bit, such as the dull measurements in FIG. 3. The wear depth can be the amount of material worn off of and/or the shape of the primary cutter after drilling with respect to the initial state of the primary cutter before drilling.

At block 406, a final bit profile of the drill bit is determined based on the wear depth for each of the primary cutters. For example, with reference to FIG. 1, a processor of the computer 170 can make this determination. The final bit profile can be determined based on the wear depth of each primary cutter of the drill bit. Similar to the process of generating the initial bit profile, the final bit profile is determined by the distribution of the worn primary cutters from operations at block 404. The worn primary cutters can then be projected onto a cartesian plot to generate a final element wear profile. The final bit profile can be generated from the final element wear profile, such as the final element wear profile 531 in FIG. 5B. Like the initial bit profile, the final bit profile can be generated from the final element wear profile with different types of interpolation (such as one-dimensional interpolation). FIGS. 6A-6B also depict a final bit profile 602 next to the initial bit profile 601 to illustrate the amount of wear of the drill bit from drilling the wellbore.

At block 408, an N number of intermediate steps between the initial bit profile and the final bit profile are defined. For example, with reference to FIG. 1, a processor of the computer 170 can define the N number of intermediate steps. N can be defined as one or more. The intermediate steps divide the total wear on the drill bit (i.e., between the initial bit profile and the final bit profile) into increments. The N number of intermediate steps can be defined by a user or operator and/or defined by various criteria. For example, the N number of intermediate steps can be defined based on the type of drill bit, the number and type of cutters, the type of formation being drilled, the composition of the drilling fluid, the composition of the formation fluid, etc. In some embodiments, the initial bit profile corresponds to step 1, the final bit profile corresponds to step N, and the number of steps is greater than 1. For example, N can be set to 20 resulting in intermediate steps 1-20, wherein step 1 would be represented by the initial bit profile and the final bit profile would be represented by intermediate step 20. Step 1 can correspond to the depth and/or time the drill bit started drilling the wellbore and step N can correspond to the depth and/or time the drill bit stopped drilling the wellbore. Intermediate steps can correspond to a depth and/or time between the when drilling with the drill bit started and ended. For instance, if a drill bit began drilling a wellbore at 1,000 feet measured depth (MD), ended at 11,000 feet MD, and N was defined as 11, then intermediate 5 would correspond to 5,000 feet MD.

At block 410, the nonlinear wear depth of the drill bit at each of the N number of intermediate steps is determined. For example, with reference to FIG. 1, a processor of the computer 170 can make this determination. The nonlinear wear depth may represent the change in the initial bit profile at each of the N number of intermediate steps (i.e., the change in height and/or radius of the initial bit profile). The nonlinear wear depth indicates that the change in the initial bit profile at each intermediate step may not be the same. For instance, the wear depth at intermediate step two can be 0.05 inches and the wear depth at intermediate step five can be 0.08 inches. The change in height/radius does not have to be uniform across the entire initial bit profile. For example, a point on the initial bit profile closer to the center of the drill bit (i.e., a point with a radius less than 2 inches on the initial bit profile, otherwise known as the cone of the drill bit) may have less wear depth (i.e., at a radius greater than 2 inches on the initial bit profile) than a point farther away from the center of the drill bit (e.g., the shoulder of the drill bit).

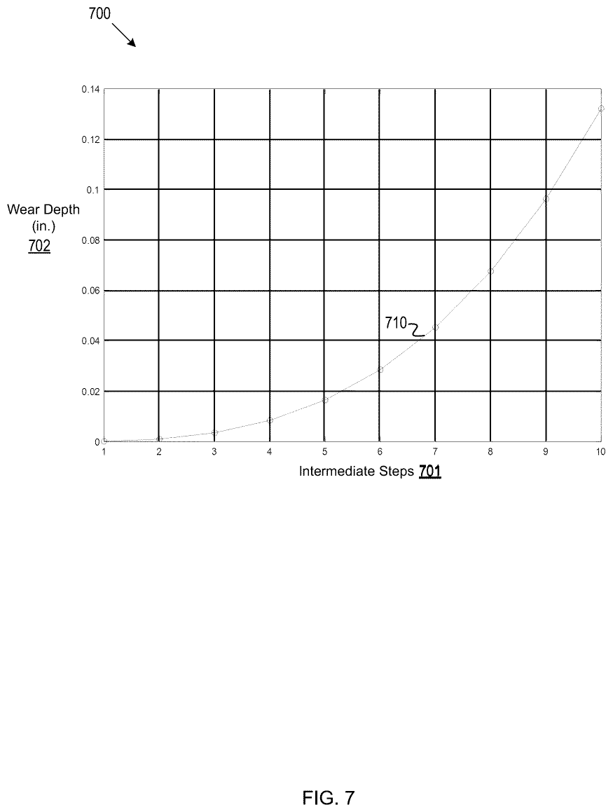

In some embodiments, a nonlinear rule can be defined to generate the wear depth at each of the N intermediate steps with respect to the initial bit profile. To illustrate, FIG. 7 depicts an example graph of wear depth over multiple intermediate steps, according to some embodiments. FIG. 7 includes a graph 700 having an x-axis 701 (that defines the intermediate steps) and a y-axis 702 (that defines the wear depth). The x-axis 701 includes 10 intermediate steps (N=10). As illustrated, the wear depth at the point at each intermediate step along the y-axis 702 increases exponentially as the drill bit drilled the wellbore. In this example, a nonlinear rule of w=k³ can be established for a drill bit, where w is the total wear depth from a point on the initial bit profile and k represents the intermediate step. If the wear depth at the point on the initial bit profile is 0.13 inches, the defined nonlinear rule can be applied to determine the wear depths 710 of that point on the initial bit profile at each intermediate step. The exponent of k can be adjusted by a user and/or system to adjust the nonlinear wear depth. In some embodiments, the rule can be linear. For example, if the total wear depth is 0.4 inches and there are 10 intermediate steps, then the exponent of k can be set to 1 and the wear depth at each step for the respective point on the initial bit profile will uniformly increase in increments of 0.04 inches.

At block 412, the intermediate step counter is set to 1 to begin operations of determining the bit design characteristics at intermediate step 1. For example, with reference to FIG. 1, a processor of the computer 170 can perform this operation.

At block 414, the intermediate bit profile at the current intermediate step is determined. For example, with reference to FIG. 1, a processor of the computer 170 can make this determination. The intermediate bit profile at the current intermediate step can be based on the wear depths at each point on the initial bit profile at the corresponding intermediate step determined in block 410.

For example, FIG. 6B depicts the initial, intermediate, and final bit profiles. The initial bit profile 601 and final bit profile 602 are determined based on the operations described in blocks 402-406. The intermediate bit profiles 610 shown in FIG. 6B are between initial bit profile 601 and final bit profile 602. A given intermediate bit profile 610 can be determined by the defined nonlinear and the wear depths determined in block 410 (described above). The height and/or radius of the intermediate bit profiles are equal to or less than the initial bit profile, representing wear at each intermediate step. As can be seen, the intermediate steps are nonlinearly divided between the initial bit profile 601 and the final bit profile 602. As shown in the graph 652 of FIG. 6B, the intermediate bit profiles 610 can be non-uniform with respect to the initial bit profile 601. For instance, the wear depths at a radius of 0.5 inches is less than the wear depths at a radius of three inches.

At block 416, the intermediate element wear profile for each element is determined based on the intermediate bit profile at the current intermediate step. For example, with reference to FIG. 1, a processor of the computer 170 can make this determination. Elements of the drill bit can include primary cutters, backup cutters, DOCCs, etc. A distribution of the elements can be displayed on a spherical coordinate system. The intermediate bit profile can then be applied to the spherical coordinate system and rotated about the central axis (corresponding to the center of the bit) 360 degrees. Any section of each of the distribution of elements that has a height and/or radius greater than or equal to the intermediate bit profile can be omitted, leaving only the remaining sections of the distribution of elements (i.e., sections of the distribution of elements with a height and/or radius less or equal to than intermediate profile). The remaining sections of the distribution of elements can then be projected into a cartesian coordinate system to generate an intermediate element wear profile for each element. The intermediate element wear profiles comprise the remaining sections of each element.

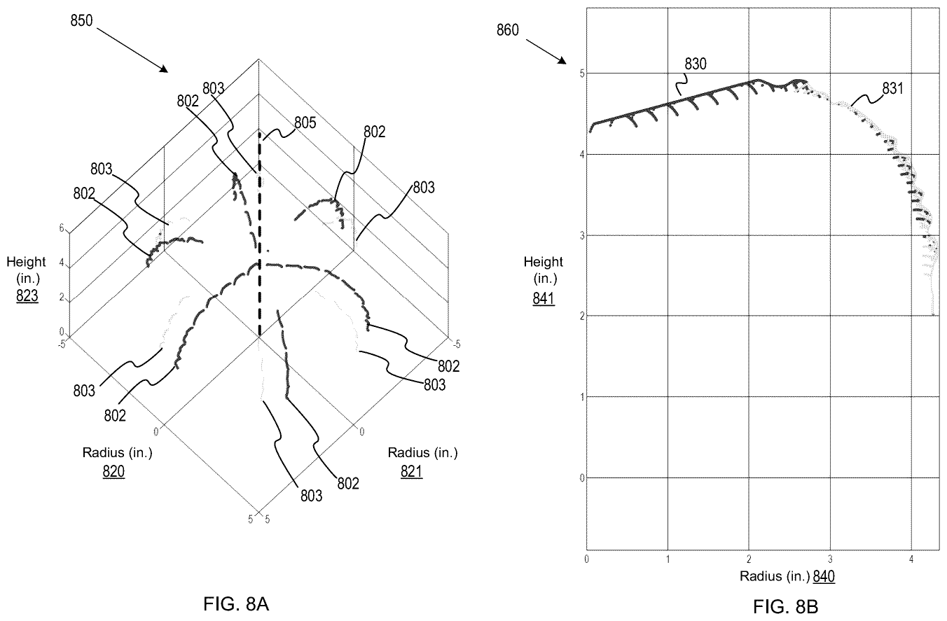

To illustrate the determination of the intermediate element wear profile, FIG. 8A-8B depict an example three-dimensional (3D) distribution of elements and an associated intermediate element wear profile, respectively, according to some embodiments. FIG. 8A depicts a spherical coordinate system 850 having an x-axis 820 a y-axis 821, and a z-axis 823. The x-axis 820 and the y-axis 821 are the radius of the drill bit in their respective directions and having units of inches (in.). The z-axis 823 is the height of the drill bit and also having units of inches (in.). The intermediate bit profile determined in block 414 can be applied to the spherical coordinate system 850 and rotated 360 degrees around the central axis 805. Any sections of primary cutters 802 and backup cutters 803 with a radius and/or height greater than or equal to the intermediate bit profile can be omitted. The remaining sections of primary cutters 802 and backup cutters 803 can then be projected to cartesian coordinate system 860 to display the intermediate element wear profiles. The cartesian coordinate system 860 includes an x-axis 840 that is the radius of the drill bit and a y-axis 841 that is the height of the drill bit. Both the x-axis 840 and the y-axis 841 have units of inches (in.). Intermediate element wear profiles comprise profiles for all elements such as an intermediate primary cutter profile 830 and an intermediate backup cutter profile 831. In some embodiments, the distribution of elements can be projected on to cartesian coordinate system before intermediate bit profile is applied. The intermediate bit profile can be applied to the cartesian coordinate system 860 over the initial element wear profiles, and then omit sections of elements in the cartesian coordinate system 860 with heights and/or radii greater than the intermediate bit profile to generate the intermediate element wear profiles 830, 831.

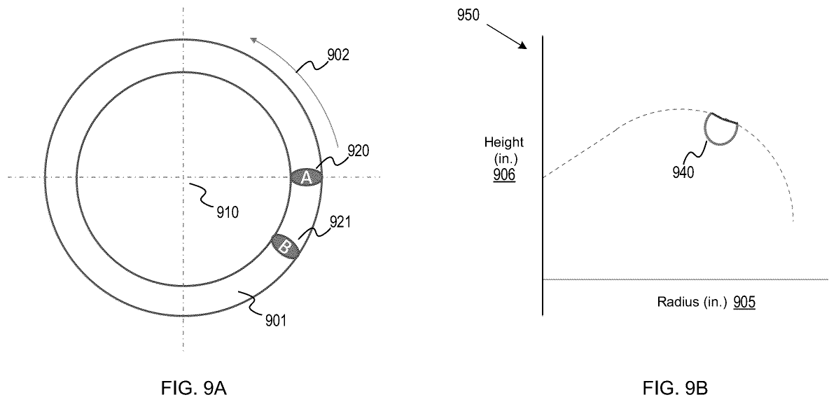

In some instances, it can be assumed that when the primary dull of the drill bit is abrasive wear, the primary cutters and backup cutters that are on the same radial track will have the same intermediate and/or final element wear profile. For example, FIG. 9A-9B depict a radial path of a pair of track-set cutters and the combined element wear profile of the track-set cutters, respectively, according to some embodiments. FIG. 9A illustrates the relation of primary cutter A 920 and backup cutter B 921 as they rotate around the center point 910 of a drill bit. Both primary cutter A 920 and backup cutter B 921 travel along the same track 901. Because primary cutter A 920 will cut the rock before backup cutter 921 due to the rotational motion 902 of the drill bit, backup cutter B 921 will be forced to have the same wear profile as primary cutter A 920. FIG. 9B illustrates the combined element wear profile 940 of primary cutter A 920 and backup cutter B 921 in a cartesian coordinate system 950. The cartesian coordinate system 950 includes an x-axis 905 that is the radius of the drill bit and a y-axis 906 that is the height of the drill bit. Both the x-axis 905 and the y-axis 906 have units of inches (in.).

At block 418, a multi-dimensional bottom hole representation of the drill bit is created. For example, with reference to FIG. 1, a processor of the computer 170 can perform this operation. For instance, a three-dimensional bottom hole representation can be generated by rotating the intermediate bit profile at least 360 degrees around a central axis in a spherical and/or cartesian coordinate system. By rotating the intermediate bit profile, an inverse intermediate bit profile can be generated that represents the shape of the rock in a subsurface formation that is drilled by the drill bit.

At block 420, a drill bit-rock interaction simulation is executed. For example, with reference to FIG. 1, a processor of the computer 170 can perform this operation. The drill bit-rock interaction simulation uses the intermediate element wear profile and the three-dimensional bottom hole representation of the drill bit to simulate the interaction between the elements and the rock of a subsurface formation. In the simulation(s), the three-dimensional bottom hole representation of the drill bit can be fixed while the intermediate element wear profiles rotate around the central axis. As the intermediate element wear profiles rotate, the simulation simulates the elements removing rock with each rotation. The drill bit-rock simulation interaction can be based on prescribed bit motions. Bit motions may include steady state bit motion (i.e., steady state ROP or steady state WOB), drilling with a mud motor, directional drilling, whirl motion, stick-slip motion, and off-center drilling. The bit motion may be prescribed based on the type of motion that was encountered while drilling the wellbore. Parameters that can be used in the simulation may include rock properties of the subsurface formation being drilled, ROP, WOB, drill bit RPM and the length of time the drill bit drilled. In some instances, the drill bit abrasive wear simulator may also incorporate data obtained from the drilling process, such as vibration data and other downhole sensor data, into the simulation.

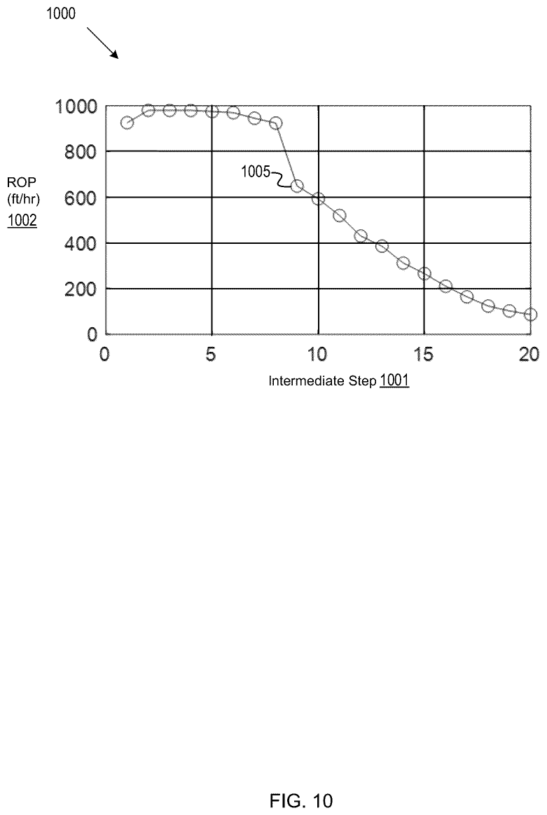

The drill bit-rock interaction simulation can generate results that represent the drill bit performance based on a state of the worn drill bit. For example, FIG. 10 depicts an example graph of an ROP over a number of intermediate steps of the simulation, according to some embodiments. A graph 1000 includes a y-axis 1002 (the ROP in terms of feet per hour (ft./hr.). The graph 1000 includes an x-axis 1001 (the intermediate step of the simulation). In this example, the graph 1000 includes a curve 1005 illustrating the simulated ROP at each intermediate step generated by the drill bit-rock interaction simulation. In this example, the simulation is based on a steady state WOB bit motion, where the WOB and RPM of the drill bit were held essentially constant to determine the ROP of the drill bit at each intermediate step.

At block 422, the wear parameters for each element are determined. For example, with reference to FIG. 1, a processor of the computer 170 can make this determination.

Wear parameters may include engagement area with the subsurface formation while drilling, contact length with the subsurface formation while drilling, and the forces applied to the element. The drill bit abrasive wear simulator determines the wear parameters based on each element's engagement with the rock in the drill bit-rock interaction simulation. In some embodiments, a single cutter force model may be used to determine forces applied to each element. There can be two forces acting on each element while drilling a wellbore. A normal force, represented by F_{wp}, (using Equation 1 below) and a friction force, represented by F_{wf} (using Equation 2 below):

F_{wp}=k₃σ_{rock}A_{c} (1)

F_{wf}=μF_{wp} (2)

Where k₃ is a coefficient, σ_{rock} is rock compressive strength (psi), A_{c} is the contact area (in²) and μ is friction coefficient. σ_{rock} may be based on the rock that is being drilling by the drill bit. A_{c} is a function of the depth of cut made by the element, the element back rake angle, and the element side rake angle. μ can be based on the rock properties and the element material(s).

At block 424, the drill bit design characteristics are determined for the current intermediate step. For example, with reference to FIG. 1, a processor of the computer 170 can make this determination. Drill bit design characteristics include drilling efficiency, bit side cutting efficiency (SCE), bit whirl index, total DOCC contact area, total axial force on the DOCCs, and total torque on the DOCCs. The drill bit design characteristics can be based on the wear parameters of each element, determined in block 422. In some embodiments, the forces acting on each element can be summed up to determine the forces acting on the drill bit. For example, the sum of the axial forces acting on each element is the simulated WOB.

At block 426, a determination is made of whether the intermediate step counter is equal to N. For example, with reference to FIG. 1, a processor of the computer 170 can make this determination. If intermediate step counter is equal to N, then operations of the flowchart 400 are complete. Otherwise, operations of the flowchart 400 continue at block 428.

At block 428, the increment counter is incremented by one. For example, with reference to FIG. 1, a processor of the computer 170 can perform this operation. Operations of the flowchart 400 then return to the operation at block 414 to determine the intermediate bit profile at the current intermediate step.

Example operations for simulation of damaged cutters of a drill bit are now described. FIG. 11 depicts a flowchart of example operations to simulate damaged cutters of a drill bit during drilling a wellbore with the drill bit, according to some embodiments. In reference to FIG. 3, FIG. 11 depicts a flowchart 1100 of example operations at block 312 of the flowchart 300. Damaged cutters on the drill bit can be an instantaneous change to the cutter, as opposed to a gradual change over time such as when the cutter is worn down due to abrasive wear. Damaged cutters may occur due to several reasons including high WOB or TOB, a sudden change in rock properties, and motion of the bit. The simulation may help determine drill bit design characteristics at intermediate steps of the drilling process that may be otherwise unknown due to unknown forces on the cutters of the drill bit while drilling and unknown rock properties of the subsurface formation. Example operations are described with reference to a drill bit damaged cutter simulator. The name chosen for the program code is not to be limiting on the claims. Structure and organization of a program can vary due to platform, programmer/architect preferences, programming language, etc. In addition, names of code units (programs, modules, methods, functions, etc.) can vary for the same reasons and can be arbitrary. The operations of flowchart 1100 divide the simulation into steps such that bit design characteristics can be determined at intermediate steps between when the drill bit is new and when the drill bit is pulled from the wellbore after it has drilled said wellbore. For the example operations in flowchart 1100, the subject drill bit has a primary dull of damaged cutters, which may be determined by the operations described in FIG. 3. Operations of the flowchart 1100 start at block 1102.

At block 1102, an initial element profile for each element of a drill bit prior to being used to drill a wellbore is determined. For example, with reference to FIG. 1, a processor of the computer 170 can make this determination. Similar methods used in block 402 of flowchart 400 can be used to display the distribution of the elements on a spherical coordinate system and then project the distribution of the elements into a cartesian coordinate system to generate the initial element profile. Elements may include primary cutters, backup cutters, DOCCs, and pads.

At block 1104, the wear depth of each element is determined after the drill bit has drilled at least a portion of a wellbore. For example, with reference to FIG. 1, a processor of the computer 170 can make this determination. Wear depths of each element can be determined using similar methods described to determine wear depths of the primary cutters in block 404 of flowchart 400.

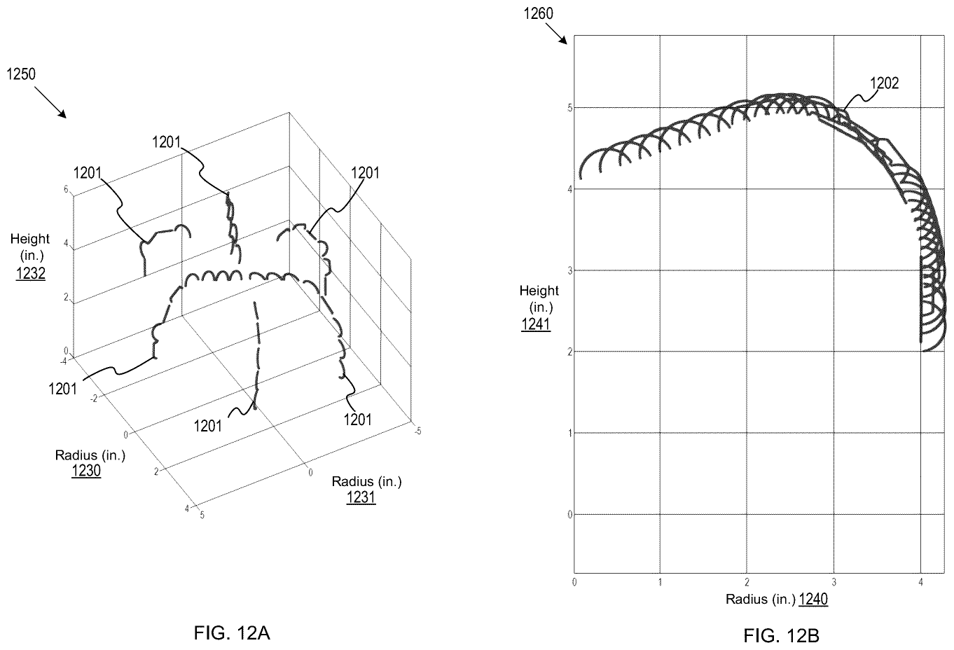

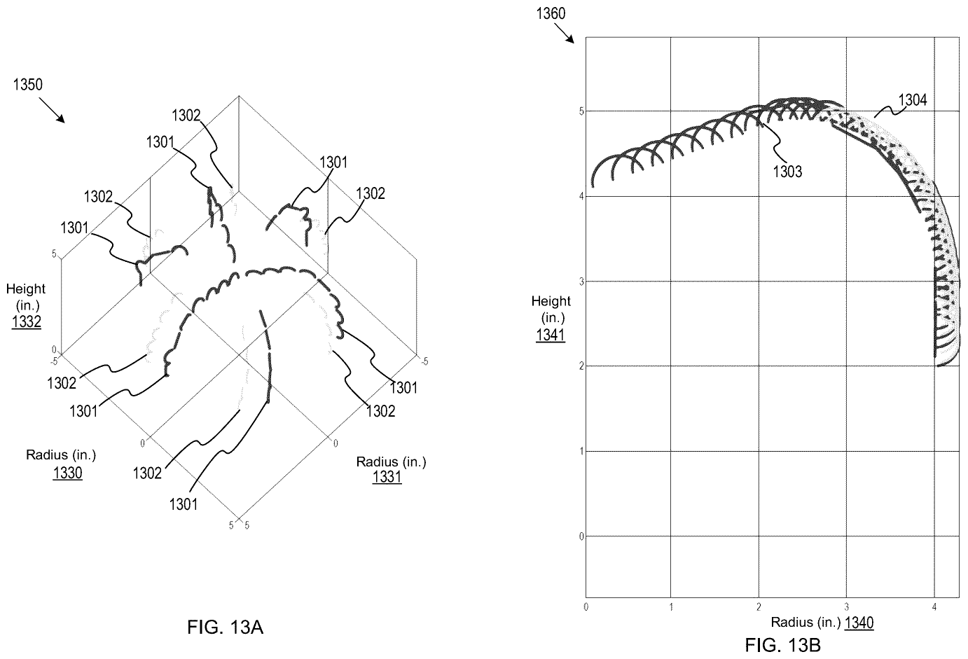

At block 1106, a final element wear profile for each element is determined. For example, with reference to FIG. 1, a processor of the computer 170 can make this determination. The final element wear profiles can be determined by methods similar to the method of determining the final element wear profiles in block 406 of flowchart 400. The final element wear profiles can be based on the wear depths of each element determined in block 1104. In some instances, all elements can be used because the elements that share the radial track (i.e., a primary cutter and backup cutter) are not assumed to have the same wear profile. For example, during the drilling of a wellbore, a primary cutter may break, resulting in the depth of cut of the primary cutter being reduced to less than the depth of cut of the backup cutter that is on the same radial track. The backup cutter may remain in contact with the rock while the primary cutter may not remain in contact with the rock, therefore creating different wear depths and ultimately element wear profiles for each of the elements. To help illustrate, FIG. 12A-12B depict an example three-dimensional (3D) distribution of primary cutters and associated primary cutter profiles, respectively, according to some embodiments. Additionally, FIG. 13A-13B depict an example three-dimensional (3D) distribution of both primary cutters and backup cutters and associated primary cutter profiles and backup cutter profiles, respectively, according to some embodiments.

FIG. 12A depicts a spherical coordinate system 1250 having an x-axis 1230, a y-axis 1231, and a z-axis 1232. The x-axis 1230 and the y-axis 1231 are the radius of the drill bit in their respective directions and having units of inches (in.). The z-axis 1232 is the height of the drill bit and also having units of inches (in.). The spherical coordinate system 1250 depicts the distribution of primary cutters 1201. Similar methods described in block 402 of flowchart 400 can be used to project the distribution of primary cutters 1201 on to a cartesian coordinate system 1260 to create final primary cutter profiles 1202, as displayed in FIG. 12B. The cartesian coordinate system 1260 includes an x-axis 1240 that is the radius of the drill bit and a y-axis 1241 that is the height of the drill bit. Both the x-axis 1240 and the y-axis 1241 have units of inches (in.).

FIG. 13A depicts a spherical coordinate system 1350 having an x-axis 1330, a y-axis 1331, and a z-axis 1332. The x-axis 1330 and the y-axis 1331 are the radius of the drill bit in their respective directions and having units of inches (in.). The z-axis 1332 is the height of the drill bit and also having units of inches (in.). The spherical coordinate system 1350 depicts the distribution of primary cutters 1301 and backup cutters 1302. Similar methods described in block 402 of flowchart 400 can be used to project the distribution of primary cutters 1301 and backup cutters 1302 on to a cartesian coordinate system 1360 to create final primary cutter profiles 1303 and backup cutter profiles 1304, as displayed in FIG. 13B. FIG. 13B depicts a cartesian coordinate system 1360 having an x-axis 1340 that is the radius of the drill bit and a y-axis 1341 that is the height of the drill bit. Both the x-axis 1340 and the y-axis 1341 have units of inches (in.). As shown by final primary cutter profiles 1303 and backup cutter profiles 1304, even though a portion of the final primary cutter wear profiles 1303 are flat due to damaged primary cutters, final backup cutter wear profiles 1304 can extend past the final primary cutter wear profiles (i.e., have a radius/height greater than the final primary cutter wear profiles). In some instances, one or more backup cutters can also be damaged such that the one or more final backup cutter wear profiles may appear similar to the final primary cutter wear profiles that are on the same radial track.

At block 1108, an N number of intermediate steps between the initial element wear profiles and the final element wear profiles for each element are defined. For example, with reference to FIG. 1, a processor of the computer 170 can define the N number of intermediate steps. The intermediate steps divide the total wear on each element into increments. The intermediate steps can be similar to those defined in block 408 of flowchart 400. For example, the initial element wear profile may correspond to step 1, the final element wear profile may correspond to step N, and the number of steps is greater than 1.

At block 1110, the nonlinear wear depth of each element at each of the N number of intermediate steps is determined. For example, with reference to FIG. 1, a processor of the computer 170 can make this determination. Similar methods described in block 410 of flowchart 400 can be used to determine the nonlinear wear depth. For example, a nonlinear rule can be defined to determine the nonlinear wear depth of each element such as the nonlinear rule depicted in FIG. 7. The nonlinear wear depth of each element can be independent from other elements. For example, a first primary cutter may have a total wear depth of 0.1 inches and a second primary cutter may have a total wear depth of 0.12 inches. The wear depth at each of the N number of intermediate steps for the respective primary cutter will differ based on the different total wear depths. Similar to operations in block 410 of flowchart 400, the defined rule can be linear in some embodiments.

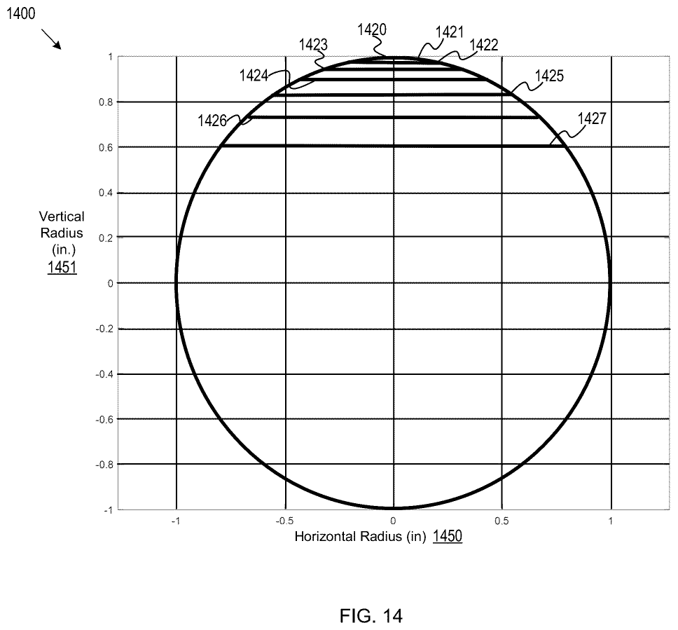

FIG. 14 depicts an example graph of a horizontal radius versus a vertical radius versus of a cutter face having nonlinear wear depths, according to some embodiments. A graph 1400 includes an x-axis 1450 and a y-axis 1451 that is the horizontal and vertical radius, respectively, of the cutter face. For this example, N is equal to 8 and a nonlinear rule has been defined. Intermediate step one (i.e., the initial element wear profile) is at a line 1420 when there is zero wear or damage on the cutter face. Lines 1421-1427 represents intermediate steps two-eight, respectively. The line 1427 represents the total wear on the cutter face (i.e., the final element wear profile). As shown, the space between the lines 1421-1427 increase exponentially due to the defined nonlinear rule.

At block 1112, the intermediate step counter is set to 1 to begin operations of determining the bit design characteristics at intermediate step 1. For example, with reference to FIG. 1, a processor of the computer 170 can perform this operation.

At block 1114, an intermediate element wear profile for each element at the current intermediate step is determined. For example, with reference to FIG. 1, a processor of the computer 170 can make this determination. The intermediate element wear profiles can be based on the nonlinear wear depths at the corresponding intermediate stage determined in block 1110. The intermediate element wear profiles can be depicted on a cartesian coordinate system such as cartesian coordinate system 1360 in FIG. 13B. The intermediate element wear profiles can also be projected to a spherical coordinate system such as spherical coordinate system 1350 of FIG. 13A. The intermediate element wear profiles displayed in the cartesian and/or spherical coordinate systems can include at least one intermediate element wear profile for a primary cutter, backup cutter, DOCC, etc.

At block 1116, an intermediate bit profile based on the intermediate element wear profiles of the current intermediate step is determined. For example, with reference to FIG. 1, a processor of the computer 170 can make this determination. The intermediate bit profile can represent the elements that will come in contact with the rock while drilling. Accordingly, the intermediate bit profile will envelop all intermediate element profiles and represent elements with the greatest upset from each radial track. For example, a primary cutter and a backup cutter can be on the same radial track. If the primary cutter has a greater upset than the backup cutter, then the primary cutter may contact the rock and the backup cutter may not contact the rock until the primary cutter is worn and/or damaged such that the upset is less than and/or equal to the backup cutter upset. Therefore, the primary cutter will be represented in the intermediate bit profile.

At block 1118, a three-dimensional bottom hole representation of the drill bit is created. For example, with reference to FIG. 1, a processor of the computer 170 can perform this operation. The three-dimensional bottom hole representation of the drill bit can be similar to the three-dimensional bottom hole representation of the drill bit created in block 418 of flowchart 400. The three-dimensional bottom hole representation of the drill bit can also be created similarly to the method used in block 418 of flowchart 400. For example, the intermediate bit profile is rotated around a central axis in a spherical and/or cartesian coordinate system.

At block 1120, a drill bit-rock interaction simulation is executed. For example, with reference to FIG. 1, a processor of the computer 170 can perform this operation. The drill bit-rock interaction simulation can be similar to the drill bit-rock interaction simulation executed in block 420 of flowchart 400. For instance, the three-dimensional bottom hole representation of the drill bit created in block 1118 can be fixed while the intermediate element wear profiles created in block 1114 rotate around the central axis. Similar to the simulation in block 420 of flowchart 400, the drill bit-rock interaction simulation can be based on a prescribed bit motion.

In some embodiments, the drill bit damaged cutter simulator can implement historical drilling data in the simulation to incorporate the step in which the element was damaged. For instance, sudden changes to parameters for subsequent drilling operations, (i.e., TOB and ROP) may correlate to when at least one element may have been damaged. If the element was damaged at a depth corresponding to the sudden change in parameters for subsequent drilling operations, then the damage and wear depth to that element can be applied into the simulation at the intermediate step in the N number of intermediate steps that corresponds to that depth.

At block 1122, the wear parameters for each element are determined. For example, with reference to FIG. 1, a processor of the computer 170 can make this determination. The wear parameters for each element and methods for determining said wear parameters can be similar to block 422 of flowchart 400. For example, the wear parameters, such as the forces acting on each element, may be determined with a single cutter force model represented by equation 1 and equation 2.

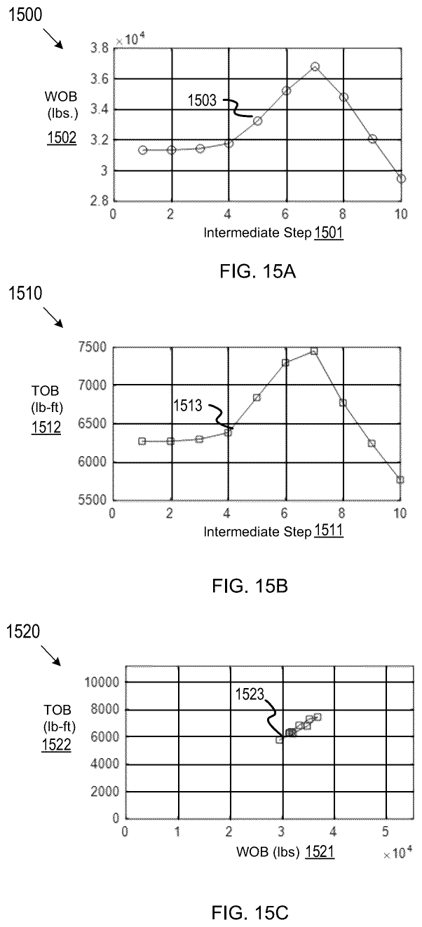

FIGS. 15A-15C depict example graphs of changes in different drill bit characteristics across intermediate steps of the simulation, according to some embodiments. FIG. 15A depicts a graph 1500 of the weight-on-bit (WOB) for a drill bit over a number of intermediate steps of the simulation. The graph 1500 includes a y-axis 1502 that is the WOB for a drill bit and having units of pounds (lbs.). The graph 1500 also includes an x-axis 1501 that is the intermediate step over the number of intermediate steps of the simulation. In this example, the graph 1500 includes a curve 1503 illustrating a simulated WOB at each intermediate step during a steady state rate of penetration (ROP) motion (i.e., the ROP is held essentially constant). As shown by the curve 1503, the simulated WOB steadily increases starting at intermediate step four and then decreases from intermediate steps seven through 10. The increase in simulated WOB may be due to an increase in wear on a primary cutter. Then at intermediate step seven, the primary cutter breaks, enabling the use of the backup cutter on the same radial track to drill the rock. Accordingly, less WOB is required with the new backup cutter to maintain the constant ROP.

FIG. 15B depicts a graph 1510 of the torque-on-bit (TOB) for a drill bit over a number of intermediate steps of the simulation. The graph 1510 includes a y-axis 1512 that is the TOB for a drill bit and having units of pound per foot (lb./ft.). The graph 1510 also includes an x-axis 1511 that is the intermediate step over the number of intermediate steps of the simulation). In this example, the graph 1510 includes a curve 1513 illustrating a simulated TOB at each intermediate step during a steady state rate of penetration (ROP) motion (i.e., the ROP is held essentially constant). As shown by the curve 1513, there is a change in the simulated TOB at intermediate stage seven when there is a sudden change in a primary cutter, such as a break.

FIG. 15C depicts a graph 1520 of the torque-on-bit (TOB) in relation to the weight-on-bit (WOB) in the steady state ROP motion. The graph 1520 includes a y-axis 1522 that is the TOB and having units of pound per foot (lb./ft.). The graph 1520 also includes an x-axis 1521 that is the WOB and having units of pounds (lbs.). In this example, the graph 1520 includes a curve 1523 illustrating the relationship between the TOB and WOB at each intermediate step.

At block 1124, the bit design characteristics for the current intermediate step is determined. For example, with reference to FIG. 1, a processor of the computer 170 can make this determination. Drill bit design characteristics include drilling efficiency, bit side cutting efficiency (SCE), bit whirl index, total DOCC contact area, total axial force on the DOCCs, and total torque on the DOCCs. The methods to determining drill bit design characteristics can be similar to that of block 424 of flowchart 400. For example, the drill bit design characteristics can be based on wear parameters of the elements determined in block 1124.

At block 1126, determination is made of whether the intermediate step counter is equal to N. For example, with reference to FIG. 1, a processor of the computer 170 can make this determination. If intermediate step counter is equal to N, then operations of the flowchart 1100 are complete. Otherwise, operations of the flowchart 1100 continue to block 1128.

At block 1128, the increment counter is incremented by one. For example, with reference to FIG. 1, a processor of the computer 170 can perform this operation. Operations of the flowchart 1100 then return to the operation at block 1114 to determine the intermediate bit profile at the current intermediate step.

### Example Multi-Well System

FIG. 16 depicts an example multi-well system, according to some embodiments. In particular, FIG. 16 is a schematic of a multi-well system 1600 that includes a well system 1601 and an offset well system 1602. Well system 1601 may include a drill sting 1614 having a drill bit 1612 disposed in a wellbore 1611 for drilling the wellbore 1611 in a subsurface formation 1650. Offset well system 1602 may include an offset wellbore 1621 that is drilled in subsurface formation 1650. In the example illustration, the wellbore 1611 and the offset wellbore 1621 are drilled in the same subsurface formations and therefore the drill bit 1612 may experience similar wear patterns as that of a drill bit (not shown) used to drill the offset wellbore 1621. In some instances, the wellbore 1611 and the offset wellbore 1621 may not be drilled in the same subsurface formation, but in different formations that can have similar rock properties. The drill bit 1612 is an example drill bit that can be designed as described herein based on abrasive wear and damage drill bit simulations performed on the drill bit used to drill the offset wellbore 1621.

The multi-well system 1600 includes a computer 1670 that may be communicatively coupled to other parts of the multi-well system 1600. The computer 1670 can be local or remote to the drilling platform of well system 1601 or offset well system 1602. A processor of the computer 1670 may have perform simulations and generate drill bit designs (as further described below). In some embodiments, the processor of the computer 1670 may control drilling operations of the well system 1601 or subsequent drilling operations of other wellbores, such as the offset well system 1602. An example of the computer 1670 is depicted in FIG. 18, which is further described below.

### Example Operations for Application of Simulations in a Multi-Well System

FIG. 17 depicts a flowchart of example operations for application of abrasive wear and/or damaged drill bit simulation in a multi-well system, according to some embodiments. FIG. 17 depicts a flowchart 1700 of operations that can design a drill bit based on abrasive wear and/or simulation results of an offset drill bit. The drill bit, such as drill bit 1612, may be designed to drill a new wellbore, such as wellbore 1611, based on the bit design characteristics of an offset run drill bit used to drill an offset wellbore, such as wellbore 1621. The operations of flowchart 1700 divide the operations into steps such that an offset run drill bit representation can be generated from bit design characteristics of an offset run drill bit to design a drill bit for the new wellbore. Operations of the flowchart 1700 are described in reference to the multi-well system 1600 of FIG. 16. Operations of the flowchart 1700 start at block 1702.

At block 1702, an offset drill bit model is generated based on bit design characteristics. For example, with reference to FIG. 16, a processor of the computer 1670 can perform this generation. The offset drill bit model characterizes the wear and/or damage for the entire run of an offset run drill bit used to drill an offset well. The intermediate steps and corresponding bit design characteristics within the offset drill bit model may be generated by methods such as the methods described in flowchart 400 and flowchart 1100. The bit design characteristics include drilling efficiency, bit side cutting efficiency (SCE), bit whirl index, total DOCC contact area, total axial force, and torque on the DOCCs.

At block 1704, the offset drill bit model is input into a force model to generate simulated values of at least one attribute of drilling a wellbore. For example, with reference to FIG. 16, a processor of the computer 1670 can perform these operations. The force model can be used to model how the offset run drill bit behaves at each intermediate step represented in the offset drill bit model. The force model may output simulated values of attributes of drilling a wellbore at each intermediate step in the offset drill bit model including surface values such as rate of penetration (ROP) and torque on the drill string as well as downhole values such as weight-on-bit (WOB) and torque-on-bit (TOB). The force model can simulate different motions and/or various scenarios to generate the simulated values at each wear state of the offset run drill bit. For instance, the ROP with a constant WOB can be simulated at each wear state. If the offset run drill bit is new and the cutters have little wear (e.g., the offset run drill bit has only drilled 1,000 feet), the ROP may be greater than at a wear state in which drill bit has drilled over 5,000 feet and may have worn or damaged cutters. In contrast, the WOB required to drill at a constant ROP at each wear state can be simulated.

At block 1706, calibration factors are determined. For example, with reference to FIG. 16, a processor of the computer 1670 can make this determination. The calibration factors can include offset wellbore data that may be obtained from various sources such as data from sensors on downhole tools of the drill string or on surface of a well system. Calibration factors may include surface ROP, surface and/or at bit WOB, and surface and/or at bit TOB and the corresponding depths and/or times.

At block 1708, the simulated values are calibrated based on the calibration factors to generate an offset run drill bit representation. For example, with reference to FIG. 16, a processor of the computer 1670 can perform these operations. The calibration of the simulated values may allow for the simulated values to accurately represent the behavior of the drill bit at each intermediate step. For example, the simulated values at an intermediate step may indicate 35,000 lbs. of WOB are required to maintain an ROP of 500 ft/hr with the current bit design characteristics. However, there may not have been 35,000 lbs of WOB at the time of drilling the intermediate step and therefore the simulated values need to be calibrated accordingly to represent actual drilling conditions.

At block 1710, a drill bit design is generated based on the offset run drill bit representation and known design correlations. For example, with reference to FIG. 16, a processor of the computer 1670 can perform this generation. The offset run drill bit representation can be used as a baseline design for the drill bit design. Changes can then be made to the drill bit design to iterate the baseline design. For instance, in an iteration the number of blades, number of cutters, and cutter positioning can be kept the same and the cutter type can be changed. Design correlations can be used to assess the performance impact of the design changes made to the baseline design. In some embodiments, the design correlations are relative to the baseline simulation values. For example, a new cutter that is 10% more wear resistant than the cutter in the baseline design is used for the new drill bit design. The relative change in ROP with respect to the offset run drill bit representation can be used to evaluate the impact the new cutters have on the drill bit performance. The new cutter will decrease wear by 10%, and therefore increase ROP and bit life relative to the offset run drill bit representation.

The flowcharts are provided to aid in understanding the illustrations and are not to be used to limit scope of the claims. The flowcharts depict example operations that can vary within the scope of the claims. Additional operations may be performed; fewer operations may be performed; the operations may be performed in parallel; and the operations may be performed in a different order. For example, the operations depicted in blocks 402-426 of flowchart 400 can be performed in parallel or concurrently. With respect to FIG. 4 and FIG. 11, a drill bit abrasive wear simulator and drill bit damaged cutter simulator, respectively, is not necessary. It will be understood that each block of the flowchart illustrations and/or block diagrams, and combinations of blocks in the flowchart illustrations and/or block diagrams, can be implemented by program code. The program code may be provided to a processor of a general-purpose computer, special purpose computer, or other programmable machine or apparatus.

As will be appreciated, aspects of the disclosure may be embodied as a system, method or program code/instructions stored in one or more machine-readable media. Accordingly, aspects may take the form of hardware, software (including firmware, resident software, micro-code, etc.), or a combination of software and hardware aspects that may all generally be referred to herein as a “circuit,” “module” or “system.” The functionality presented as individual modules/units in the example illustrations can be organized differently in accordance with any one of platform (operating system and/or hardware), application ecosystem, interfaces, programmer preferences, programming language, administrator preferences, etc.

Any combination of one or more machine-readable medium(s) may be utilized. The machine-readable medium may be a machine-readable signal medium or a machine-readable storage medium. A machine-readable storage medium may be, for example, but not limited to, a system, apparatus, or device, that employs any one of or combination of electronic, magnetic, optical, electromagnetic, infrared, or semiconductor technology to store program code. More specific examples (a non-exhaustive list) of the machine-readable storage medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, a magnetic storage device, or any suitable combination of the foregoing. In the context of this document, a machine-readable storage medium may be any tangible medium that can contain or store a program for use by or in connection with an instruction execution system, apparatus, or device. A machine-readable storage medium is not a machine-readable signal medium.

A machine-readable signal medium may include a propagated data signal with machine readable program code embodied therein, for example, in baseband or as part of a carrier wave. Such a propagated signal may take any of a variety of forms, including, but not limited to, electro-magnetic, optical, or any suitable combination thereof. A machine-readable signal medium may be any machine-readable medium that is not a machine-readable storage medium and that can communicate, propagate, or transport a program for use by or in connection with an instruction execution system, apparatus, or device.

Program code embodied on a machine-readable medium may be transmitted using any appropriate medium, including but not limited to wireless, wireline, optical fiber cable, RF, etc., or any suitable combination of the foregoing.

Computer program code for carrying out operations for aspects of the disclosure may be written in any combination of one or more programming languages, including an object oriented programming language such as the Java® programming language, C++ or the like; a dynamic programming language such as Python; a scripting language such as Perl programming language or PowerShell script language; and conventional procedural programming languages, such as the “C” programming language or similar programming languages. The program code may execute entirely on a stand-alone machine, may execute in a distributed manner across multiple machines, and may execute on one machine while providing results and or accepting input on another machine.

The program code/instructions may also be stored in a machine-readable medium that can direct a machine to function in a particular manner, such that the instructions stored in the machine-readable medium produce an article of manufacture including instructions which implement the function/act specified in the flowchart and/or block diagram block or blocks.

### Example Computer

FIG. 18 depicts an example computer, according to some embodiments. FIG. 18 depicts a computer 1800 that includes a processor 1801 (possibly including multiple processors, multiple cores, multiple nodes, and/or implementing multi-threading, etc.). The computer 1800 includes a memory 1807. The memory 1807 may be system memory or any one or more of the above already described possible realizations of machine-readable media. The computer 1800 also includes a bus 1803 and a network interface 1805.

The computer 1800 also includes a simulation processor 1811 and a controller 1815. The simulation processor 1811 and the controller 1815 can perform one or more of the operations described herein. For example, the simulation processor 1811 can perform the abrasive wear and/or damage simulation for a drill bit. The controller 1815 can perform various control operations to a wellbore operation based on the simulations. For example, the controller 1815 can modify a drilling operation based on the simulations.

Any one of the previously described functionalities may be partially (or entirely) implemented in hardware and/or on the processor 1801. For example, the functionality may be implemented with an application specific integrated circuit, in logic implemented in the processor 1801, in a co-processor on a peripheral device or card, etc. Further, realizations may include fewer or additional components not illustrated in FIG. 18 (e.g., video cards, audio cards, additional network interfaces, peripheral devices, etc.). The processor 1801 and the network interface 1805 are coupled to the bus 1803. Although illustrated as being coupled to the bus 1803, the memory 1807 may be coupled to the processor 1801.

While the aspects of the disclosure are described with reference to various implementations and exploitations, it will be understood that these aspects are illustrative and that the scope of the claims is not limited to them. In general, techniques for simulating drill bit abrasive wear and damage during the drilling of a wellbore as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the disclosure. In general, structures and functionality presented as separate components in the example configurations may be implemented as a combined structure or component. Similarly, structures and functionality presented as a single component may be implemented as separate components. These and other variations, modifications, additions, and improvements may fall within the scope of the disclosure.

### Example Embodiments

Embodiment #1: A method comprising: determining an initial bit profile of a drill bit prior to the drill bit being used for drilling a wellbore; determining a wear depth for at least one element of the drill bit after the drill bit has drilled at least a portion of the wellbore; determining a final bit profile of the drill bit based on the wear depth for the at least one element of the drill bit; and performing the following for each of one or more intermediate steps between the initial bit profile and the final bit profile, determining an intermediate bit profile of the drill bit; and determining at least one wear parameter for the at least one element based on the intermediate bit profile of the drill bit.
Embodiment #2: The method of Embodiment #1, wherein performing the following for each of the one or more intermediate steps comprises, determining an intermediate element wear profile for the at least one element based on the intermediate bit profile, wherein determining the at least one wear parameter for the at least one element comprises determining the at least one wear parameter for the at least one element based on the intermediate element wear profile for the at least one element.
Embodiment #3: The method of Embodiment #2, wherein performing the following for each of the one or more intermediate steps comprises, executing a drill bit-rock interaction simulation according to a drill bit motion, wherein the drill bit-rock interaction simulation is based on the intermediate bit profile and the intermediate element wear profile for the at least one element, wherein determining the at least one wear parameter for the at least one element comprises determining the at least one wear parameter for the at least one element based on the drill bit-rock interaction simulation.
Embodiment #4: The method of Embodiment #3, wherein the drill bit motion comprises at least one of a steady state bit motion, a drilling with a motion, and a directional drilling motion.
Embodiment #5: The method of one or more of Embodiments #1-4, wherein performing the following for each of the one or more intermediate steps comprises determining at least one bit design characteristic based on the at least one wear parameter.
Embodiment #6: The method of Embodiment #5 further comprising: generating an offset drill bit model based on the at least one bit design characteristic; generating simulated values of at least one attribute of drilling of a different wellbore based on inputting the offset drill bit model into a force model; determining at least one calibration factor for the at least one attribute of the drilling of the different wellbore; calibrating the simulated values based on the at least one calibration factor; generating an offset run drill bit representation based on the calibrated simulated values; and generating a drill bit design, based on the offset run drill bit representation, for a different drill bit to be used to drill the different wellbore.
Embodiment #7: The method of Embodiment #6, wherein the at least one attribute of drilling of the different wellbore comprises at least one of a surface rate of penetration, a surface torque on the drill string that includes the drill bit, a weight on the drill bit, and a torque on the drill bit.
Embodiment #8: The method of one or more of Embodiments #1-7, wherein the at least one wear parameter comprises at least one of an engagement area of the at least one element with a subsurface formation in which the wellbore is drilled, a contact length of the at least one element with the subsurface formation, and at least one force on the at least one element.
Embodiment #9: A non-transitory, computer-readable medium having instructions stored thereon that are executable by a processor to perform operations comprising: determining an initial bit profile of a drill bit prior to the drill bit being used for drilling a wellbore; determining a wear depth for at least one element of the drill bit after the drill bit has drilled at least a portion of the wellbore; determining a final bit profile of the drill bit based on the wear depth for the at least one element of the drill bit; and performing the following for each of one or more intermediate steps between the initial bit profile and the final bit profile, determining an intermediate bit profile of the drill bit; and determining at least one wear parameter for the at least one element based on the intermediate bit profile of the drill bit.
Embodiment #10: The non-transitory, computer-readable medium of Embodiment #9, wherein performing the following for each of the one or more intermediate steps comprises, determining an intermediate element wear profile for the at least one element based on the intermediate bit profile, wherein determining the at least one wear parameter for the at least one element comprises determining the at least one wear parameter for the at least one element based on the intermediate element wear profile for the at least one element.
Embodiment #11: The non-transitory, computer-readable medium of Embodiment #10, wherein performing the following for each of the one or more intermediate steps comprises, executing a drill bit-rock interaction simulation according to a drill bit motion, wherein the drill bit-rock interaction simulation is based on the intermediate bit profile and the intermediate element wear profile for the at least one element, wherein determining the at least one wear parameter for the at least one element comprises determining the at least one wear parameter for the at least one element based on the drill bit-rock interaction simulation.
Embodiment #12: The non-transitory, computer-readable medium of Embodiment #11, wherein the drill bit motion comprises at least one of a steady state bit motion, a drilling with a motion, and a directional drilling motion.
Embodiment #13: The non-transitory, computer-readable medium of any one of Embodiments #9-12, wherein performing the following for each of the one or more intermediate steps comprises, determining at least one bit design characteristic based on the at least one wear parameter.
Embodiment #14: The non-transitory, computer-readable medium of Embodiment #13, wherein the operations comprise: generating an offset drill bit model based on the at least one bit design characteristic; generating simulated values of at least one attribute of drilling of a different wellbore based on inputting the offset drill bit model into a force model; determining at least one calibration factor for the at least one attribute of the drilling of the different wellbore; calibrating the simulated values based on the at least one calibration factor; generating an offset run drill bit representation based on the calibrated simulated values; and generating a drill bit design, based on the offset run drill bit representation, for a different drill bit to be used to drill the different wellbore.
Embodiment #15: The non-transitory, computer-readable medium of Embodiment #14, wherein the at least one attribute of drilling of the different wellbore comprises at least one of a surface rate of penetration, a surface torque on the drill string that includes the drill bit, a weight on the drill bit, and a torque on the drill bit.
Embodiment #16: The non-transitory, computer-readable medium of any one of Embodiments #9-15, wherein the at least one wear parameter comprises at least one of an engagement area of the at least one element with a subsurface formation in which the wellbore is drilled, a contact length of the at least one element with the subsurface formation, and at least one force on the at least one element.
Embodiment #17: An apparatus comprising: a processor; and a computer-readable medium having instructions stored thereon that are executable by the processor to cause the processor to determine an initial bit profile of a drill bit prior to the drill bit being used for drilling a wellbore; determine a wear depth for at least one element of the drill bit after the drill bit has drilled at least a portion of the wellbore; determine a final bit profile of the drill bit based on the wear depth for the at least one element of the drill bit; and perform the following for each of one or more intermediate steps between the initial bit profile and the final bit profile, determine an intermediate bit profile of the drill bit; and determine at least one wear parameter for the at least one element based on the intermediate bit profile of the drill bit.
Embodiment #18: The apparatus of Embodiment #17, wherein the instructions that are executable by the processor to cause the processor to perform the following for each of the one or more intermediate steps comprises instructions that are executable by the processor to cause the processor to determine an intermediate element wear profile for the at least one element based on the intermediate bit profile, wherein the instructions that are executable by the processor to cause the processor to determine the at least one wear parameter for the at least one element comprises instructions that are executable by the processor to cause the processor to determine the at least one wear parameter for the at least one element based on the intermediate element wear profile for the at least one element.
Embodiment #19: The apparatus of any one of Embodiments #17-18, wherein the instructions that are executable by the processor to cause the processor to perform the following for each of the one or more intermediate steps comprises instructions that are executable by the processor to cause the processor to determine at least one bit design characteristic based on the at least one wear parameter.
Embodiment #20: The apparatus of Embodiment #19, wherein the instructions comprise that are executable by the processor to cause the processor to generate an offset drill bit model based on the at least one bit design characteristic; generate simulated values of at least one attribute of drilling of a different wellbore based on inputting the offset drill bit model into a force model, wherein the at least one attribute of drilling of the different wellbore comprises at least one of a surface rate of penetration, a surface torque on the drill string that includes the drill bit, a weight on the drill bit, and a torque on the drill bit; determine at least one calibration factor for the at least one attribute of the drilling of the different wellbore; calibrate the simulated values based on the at least one calibration factor; generate an offset run drill bit representation based on the calibrated simulated values; and generate a drill bit design, based on the offset run drill bit representation, for a different drill bit to be used to drill the different wellbore.
Embodiment #21: A method comprising: determining an initial element wear profile of at least one element of a drill bit prior to the drill bit being used for drilling a wellbore; determining a wear depth for each of the at least one element of the drill bit after the drill bit has drilled at least a portion of the wellbore; determining a final element wear profile of the at least one element of the drill bit based on the wear depth of the at least one element of the drill bit; and performing the following for each of one or more of intermediate steps between the initial element wear profile and the final element wear profile, determining an intermediate element wear profile of the at least one element; and determining at least one wear parameter for the at least one element based on the intermediate element wear profile.
Embodiment #22: The method of Embodiment #21, wherein performing the following for each of the one or more intermediate steps comprises: determining an intermediate bit profile of the drill bit based on the intermediate element wear profile of the at least one element, wherein determining the at least one wear parameter for the at least one element comprises determining the at least one wear parameter for the at least one element based on the intermediate element wear profile of the at least one element.
Embodiment #23: The method of Embodiment #22, wherein performing the following for each of the one or more intermediate steps comprises: executing a drill bit-rock interaction simulation according to a drill bit motion, wherein the drill bit-rock interaction simulation is based on the intermediate element wear profile of the at least one element and the intermediate bit profile, wherein determining the at least one wear parameter for the at least one element comprises determining the at least one wear parameter for the at least one element based on drill bit-rock interaction simulation.
Embodiment #24: The method of Embodiment #23, wherein the drill bit motion comprises at least one of a steady state bit motion, a drilling with a motion, and a directional drilling motion.
Embodiment #25: The method of any one of Embodiments #21-24, wherein performing the following for each of the one or more intermediate steps comprises determining at least one bit design characteristic based on the at least one wear parameter.
Embodiment #26: The method of Embodiment #25 further comprising: generating an offset drill bit model based on the at least one bit design characteristic; generating simulated values of at least one attribute of drilling of a different wellbore based on inputting the offset drill bit model into a force model; determining at least one calibration factor for the at least one attribute of the drilling of the different wellbore; calibrating the simulated values based on the at least one calibration factor; generating an offset run drill bit representation based on the calibrated simulated values; and generating a drill bit design based on the offset run digital drill bit representation, for a different drill bit to be used to drill the different wellbore.
Embodiment #27: The method of Embodiment #26, wherein the at least one attribute of drilling of the different wellbore comprises at least one of a surface rate of penetration, a surface torque on the drill string that includes the drill bit, a weight on the drill bit, and a torque on the drill bit.
Embodiment #28: The method of any one of Embodiments #21-28, wherein the at least one wear parameter comprises at least one of an engagement area of the at least one element with a subsurface formation in which the wellbore is drilled, a contact length of the at least one element with the subsurface formation, and at least one force on the at least one element.
Embodiment #29: A non-transitory, computer-readable medium having instructions stored thereon that are executable by a processor to perform operations comprising: determining an initial element wear profile of at least one element of a drill bit prior to the drill bit being used for drilling a wellbore; determining a wear depth for each of the at least one element of the drill bit after the drill bit has drilled at least a portion of the wellbore; determining a final element wear profile of the at least one element of the drill bit based on the wear depth of the at least one element of the drill bit; and performing the following for each of one or more intermediate steps between the initial element wear profile and the final element wear profile, determining an intermediate element wear profile of the at least one element; and determining at least one wear parameter for the at least one element based on the intermediate element wear profile.
Embodiment #30: The non-transitory, computer-readable medium of Embodiment #29, wherein performing the following for each of the one or more intermediate steps comprises: determining an intermediate bit profile of the drill bit based on the intermediate element wear profile of the at least one element, wherein determining the at least one wear parameter for the at least one element comprises determining the at least one wear parameter for the at least one element based on the intermediate element wear profile of the at least one element.
Embodiment #31: The non-transitory, computer-readable medium of Embodiment #30, wherein performing the following for each of the one or more intermediate steps comprises: executing a drill bit-rock interaction simulation according to a drill bit motion, wherein the drill bit-rock interaction simulation is based on the intermediate element wear profile of the at least one element and the intermediate bit profile, wherein determining the at least one wear parameter for the at least one element comprises determining the at least one wear parameter for the at least one element based on drill bit-rock interaction simulation.
Embodiment #32: The non-transitory, computer-readable medium of Embodiment #31, wherein the drill bit motion comprises at least one of a steady state bit motion, a drilling with a motion, and a directional drilling motion.
Embodiment #33: The non-transitory, computer-readable medium of any one of Embodiments #29-32, wherein performing the following for each of the one or more intermediate steps comprises determining at least one bit design characteristic based on the at least one wear parameter.
Embodiment #34: The non-transitory, computer-readable medium of Embodiment #33, wherein the operations comprise: generating an offset drill bit model based on the at least one bit design characteristic; generating simulated values of at least one attribute of drilling of a different wellbore based on inputting the offset drill bit model into a force model; determining at least one calibration factor for the at least one attribute of the drilling of the different wellbore; calibrating the simulated values based on the at least one calibration factor; generating an offset run drill bit representation based on the calibrated simulated values; and generating a drill bit design based on the offset run digital drill bit representation, for a different drill bit to be used to drill the different wellbore.
Embodiment #35: The non-transitory, computer-readable medium of Embodiment #34, wherein the at least one attribute of drilling of the different wellbore comprises at least one of a surface rate of penetration, a surface torque on the drill string that includes the drill bit, a weight on the drill bit, and a torque on the drill bit.
Embodiment #36: The non-transitory, computer-readable medium of any one of Embodiments #29-35, wherein the at least one wear parameter comprises at least one of an engagement area of the at least one element with a subsurface formation in which the wellbore is drilled, a contact length of the at least one element with the subsurface formation, and at least one force on the at least one element.
Embodiment #37: An apparatus comprising: a processor; and a computer-readable medium having instructions stored thereon that are executable by the processor to cause the processor to, determine an initial element wear profile of at least one element of a drill bit prior to the drill bit being used for drilling a wellbore; determine a wear depth for each of the at least one element of the drill bit after the drill bit has drilled at least a portion of the wellbore; and determine a final element wear profile of the at least one element of the drill bit based on the wear depth of the at least one element of the drill bit; and perform the following for each of one or more intermediate steps between the initial element wear profile and the final element wear profile, determine an intermediate element wear profile of the at least one element; and determine at least one wear parameter for the at least one element based on the intermediate element wear profile.
Embodiment #38: The apparatus of Embodiment #37, wherein the instructions that are executable by the processor to cause the processor to perform the following for each of the one or more intermediate steps comprises instructions that are executable by the processor to cause the processor to, determine an intermediate bit profile of the drill bit based on the intermediate element wear profile of the at least one element, wherein the instructions that are executable by the processor to cause the processor to determine the at least one wear parameter for the at least one element comprises wherein instructions that are executable by the processor to cause the processor to determine the at least one wear parameter for the at least one element based on the intermediate element wear profile of the at least one element.
Embodiment #39: The apparatus of any one of Embodiments #37-38, wherein the instructions that are executable by the processor to cause the processor to perform the following for each of the one or more intermediate steps comprises instructions that are executable by the processor to cause the processor to determine at least one bit design characteristic based on the at least one wear parameter.
Embodiment #40: The apparatus of Embodiment #39, wherein the instructions comprise that are executable by the processor to cause the processor to, generate an offset drill bit model based on the at least one bit design characteristic; generate simulated values of at least one attribute of drilling of a different wellbore based on inputting the offset drill bit model into a force model, wherein the at least one attribute of drilling of the different wellbore comprises at least one of a surface rate of penetration, a surface torque on the drill string that includes the drill bit, a weight on the drill bit, and a torque on the drill bit; determine at least one calibration factor for the at least one attribute of the drilling of the different wellbore; calibrate the simulated values based on the at least one calibration factor; generate an offset run drill bit representation based on the calibrated simulated values; and generate a drill bit design based on the offset run digital drill bit representation, for a different drill bit to be used to drill the different wellbore.

Use of the phrase “at least one of” preceding a list with the conjunction “and” should not be treated as an exclusive list and should not be construed as a list of categories with one item from each category, unless specifically stated otherwise. A clause that recites “at least one of A, B, and C” can be infringed with only one of the listed items, multiple of the listed items, and one or more of the items in the list and another item not listed.

As used herein, the term “or” is inclusive unless otherwise explicitly noted. Thus, the phrase “at least one of A, B, or C” is satisfied by any element from the set {A, B, C} or any combination thereof, including multiples of any element.

1. A method comprising:
determining an initial bit profile of a drill bit prior to the drill bit being used for drilling a wellbore;
determining a wear depth for at least one element of the drill bit after the drill bit has drilled at least a portion of the wellbore;
determining a final bit profile of the drill bit based on the wear depth for the at least one element of the drill bit; and
performing the following for each of one or more intermediate steps between the initial bit profile and the final bit profile,
determining an intermediate bit profile of the drill bit; and
determining at least one wear parameter for the at least one element based on the intermediate bit profile of the drill bit.

2. The method of claim 1, wherein performing the following for each of the one or more intermediate steps comprises,
determining an intermediate element wear profile for the at least one element based on the intermediate bit profile,
wherein determining the at least one wear parameter for the at least one element comprises determining the at least one wear parameter for the at least one element based on the intermediate element wear profile for the at least one element.

3. The method of claim 2, wherein performing the following for each of the one or more intermediate steps comprises,
executing a drill bit-rock interaction simulation according to a drill bit motion, wherein the drill bit-rock interaction simulation is based on the intermediate bit profile and the intermediate element wear profile for the at least one element,
wherein determining the at least one wear parameter for the at least one element comprises determining the at least one wear parameter for the at least one element based on the drill bit-rock interaction simulation.

4. The method of claim 3, wherein the drill bit motion comprises at least one of a steady state bit motion, a drilling with a motion, and a directional drilling motion.

5. The method of claim 1, wherein performing the following for each of the one or more intermediate steps comprises determining at least one bit design characteristic based on the at least one wear parameter.

6. The method of claim 5 further comprising:
generating an offset drill bit model based on the at least one bit design characteristic;
generating simulated values of at least one attribute of drilling of a different wellbore based on inputting the offset drill bit model into a force model;
determining at least one calibration factor for the at least one attribute of the drilling of the different wellbore;
calibrating the simulated values based on the at least one calibration factor;
generating an offset run drill bit representation based on the calibrated simulated values; and
generating a drill bit design, based on the offset run drill bit representation, for a different drill bit to be used to drill the different wellbore.

7. The method of claim 6, wherein the at least one attribute of drilling of the different wellbore comprises at least one of a surface rate of penetration, a surface torque on the drill string that includes the drill bit, a weight on the drill bit, and a torque on the drill bit.

8. The method of claim 1, wherein the at least one wear parameter comprises at least one of an engagement area of the at least one element with a subsurface formation in which the wellbore is drilled, a contact length of the at least one element with the subsurface formation, and at least one force on the at least one element.

9. A non-transitory, computer-readable medium having instructions stored thereon that are executable by a processor to perform operations comprising:
determining an initial bit profile of a drill bit prior to the drill bit being used for drilling a wellbore;
determining a wear depth for at least one element of the drill bit after the drill bit has drilled at least a portion of the wellbore;
determining a final bit profile of the drill bit based on the wear depth for the at least one element of the drill bit; and
performing the following for each of one or more intermediate steps between the initial bit profile and the final bit profile,
determining an intermediate bit profile of the drill bit; and
determining at least one wear parameter for the at least one element based on the intermediate bit profile of the drill bit.

10. The non-transitory, computer-readable medium of claim 9, wherein performing the following for each of the one or more intermediate steps comprises,
determining an intermediate element wear profile for the at least one element based on the intermediate bit profile,
wherein determining the at least one wear parameter for the at least one element comprises determining the at least one wear parameter for the at least one element based on the intermediate element wear profile for the at least one element.

11. The non-transitory, computer-readable medium of claim 10, wherein performing the following for each of the one or more intermediate steps comprises,
executing a drill bit-rock interaction simulation according to a drill bit motion, wherein the drill bit-rock interaction simulation is based on the intermediate bit profile and the intermediate element wear profile for the at least one element,
wherein determining the at least one wear parameter for the at least one element comprises determining the at least one wear parameter for the at least one element based on the drill bit-rock interaction simulation.

12. The non-transitory, computer-readable medium of claim 11, wherein the drill bit motion comprises at least one of a steady state bit motion, a drilling with a motion, and a directional drilling motion.

13. The non-transitory, computer-readable medium of claim 9, wherein performing the following for each of the one or more intermediate steps comprises,
determining at least one bit design characteristic based on the at least one wear parameter.

14. The non-transitory, computer-readable medium of claim 13, wherein the operations comprise:
generating an offset drill bit model based on the at least one bit design characteristic;
generating simulated values of at least one attribute of drilling of a different wellbore based on inputting the offset drill bit model into a force model;
determining at least one calibration factor for the at least one attribute of the drilling of the different wellbore;
calibrating the simulated values based on the at least one calibration factor;
generating an offset run drill bit representation based on the calibrated simulated values; and
generating a drill bit design, based on the offset run drill bit representation, for a different drill bit to be used to drill the different wellbore.

15. The non-transitory, computer-readable medium of claim 14, wherein the at least one attribute of drilling of the different wellbore comprises at least one of a surface rate of penetration, a surface torque on the drill string that includes the drill bit, a weight on the drill bit, and a torque on the drill bit.

16. The non-transitory, computer-readable medium of claim 9, wherein the at least one wear parameter comprises at least one of an engagement area of the at least one element with a subsurface formation in which the wellbore is drilled, a contact length of the at least one element with the subsurface formation, and at least one force on the at least one element.

17. An apparatus comprising:
a processor; and
a computer-readable medium having instructions stored thereon that are executable by the processor to cause the processor to,
determine an initial bit profile of a drill bit prior to the drill bit being used for drilling a wellbore;
determine a wear depth for at least one element of the drill bit after the drill bit has drilled at least a portion of the wellbore;
determine a final bit profile of the drill bit based on the wear depth for the at least one element of the drill bit; and
perform the following for each of one or more intermediate steps between the initial bit profile and the final bit profile,
determine an intermediate bit profile of the drill bit; and
determine at least one wear parameter for the at least one element based on the intermediate bit profile of the drill bit.

18. The apparatus of claim 17, wherein the instructions that are executable by the processor to cause the processor to perform the following for each of the one or more intermediate steps comprises instructions that are executable by the processor to cause the processor to,
determine an intermediate element wear profile for the at least one element based on the intermediate bit profile,
wherein the instructions that are executable by the processor to cause the processor to determine the at least one wear parameter for the at least one element comprises instructions that are executable by the processor to cause the processor to determine the at least one wear parameter for the at least one element based on the intermediate element wear profile for the at least one element.

19. The apparatus of claim 17, wherein the instructions that are executable by the processor to cause the processor to perform the following for each of the one or more intermediate steps comprises instructions that are executable by the processor to cause the processor to determine at least one bit design characteristic based on the at least one wear parameter.

20. The apparatus of claim 19, wherein the instructions comprise that are executable by the processor to cause the processor to,
generate an offset drill bit model based on the at least one bit design characteristic;
generate simulated values of at least one attribute of drilling of a different wellbore based on inputting the offset drill bit model into a force model, wherein the at least one attribute of drilling of the different wellbore comprises at least one of a surface rate of penetration, a surface torque on the drill string that includes the drill bit, a weight on the drill bit, and a torque on the drill bit;
determine at least one calibration factor for the at least one attribute of the drilling of the different wellbore;
calibrate the simulated values based on the at least one calibration factor;
generate an offset run drill bit representation based on the calibrated simulated values; and
generate a drill bit design, based on the offset run drill bit representation, for a different drill bit to be used to drill the different wellbore.
